(19) United States
(12) Patent Application Publication
(10) Pub. No.: US 2026/0282303 A1
(43) Pub. Date: Sep. 17, 2026

(54) SYSTEMS AND APPARATUSES FOR IMPROVING ELECTROMAGNETIC COMPATIBILITY

(71) Applicant: Pulse RX Disinfection Corp., Oakville (CA)

(72) Inventors: Rohit VERMA, Etobicoke (CA); Jose Miguel BARRIOS SIERRA, Etobicoke (CA); Treesa Shavinki Nilhara PERERA USWATTELIYANAGE, Oakville (CA)

(73) Assignee: Pulse RX Disinfection Corp., Oakville, ON (CA)

(21) Appl. No.: 19/567,478

(22) Filed: Mar. 16, 2026

Related U.S. Application Data
(60) Provisional application No. 63/771,931, filed on Mar. 14, 2025.

(51) Int. Cl. H05K 9/00

(52) U.S. Cl. CPC H05K 9/002

(57) ABSTRACT

Embodiments of the present application provide systems and apparatuses for improving electromagnetic compatibility of an equipment. An apparatus includes a first housing, a second housing, and a third housing. The first housing includes a first outer plate mounted to a first panel carrying a first component, and a first inner plate including a first lateral opening. The second housing includes a second outer plate mounted to a second panel carrying a second group of components, and a second inner plate including a second lateral opening. The second inner plate is mounted in contact with the first inner plate with the second lateral opening axially aligned with the first lateral opening. The third housing is mounted on both the first housing and the second housing. The third housing has a first opening axially aligned with the first side opening, and a second opening is axially aligned with the second side opening.

### TECHNICAL FIELD

The present application generally relates to electromagnetic shielding mechanisms and particularly to systems and apparatuses for improving electromagnetic compatibility.

### BACKGROUND

Various types of robots, such as disinfection robots, delivery robots, telepresence robots, fire-fighting robots, and agricultural robots, are available on the market. These robots generally include a chassis and an assembly of operational components (such as motors, transformers, heat sinks, capacitors, batteries, and processors) driving an electrical load. The operational components are often densely packed together, for example, on a tray secured to the chassis, to reduce the footprint of a robot. However, such a high-density configuration generally induces electromagnetic (EM) coupling between the operational components to often increase EM emissions beyond the permissible limits established by applicable regulatory standards for electromagnetic compatibility (EMC).

Electromagnetic compatibility (EMC) refers to the ability of equipment, such as robots, to operate as intended without causing or experiencing unwanted electromagnetic interference (EMI) beyond permissible limits. Regulatory standards in various countries generally govern these permissible limits. For example, in the United States, the Federal Communications Commission (FCC) regulates the permissible limits for conducted and radiated emissions from unintentional radiators under 47 C.F.R. Part 15, Subpart B. Both types of emissions generate electromagnetic noise that can disrupt the normal operation of a host equipment or nearby devices. In severe cases, such EMI caused by these conducted and radiated emissions can create a safety hazard or compromise safety-critical systems.

Conventional EMI mitigation techniques include shielding, filtering, grounding, and circuit-level layout optimization on a printed circuit board (PCB). These techniques often involve the use or adjustment of passive components such as capacitors, inductors, resistors, common-mode chokes, and ferrite elements at the circuit level to suppress conducted and radiated emissions. While these techniques may provide baseline EMI reduction, they tend to be insufficient for bringing EM emissions within permissible limits in large industrial, scientific, and medical (ISM) equipment, such as robots, particularly where removable panels or modular parts introduce variability in electrical bonding and structural continuity. In addition, high voltage switching operation can increase electric field strength and displacement currents through parasitic capacitances, thereby increasing electromagnetic coupling between the operational components. Further, a circuit-focused approach involving redesign of the PCB layout, such as modifying the number, type, or placement of passive components, can significantly increase time-to-market, manufacturing complexity, and developmental and operational costs.

Therefore, there is a continuous need for system-level EMC configuration and mitigation techniques that are independent of PCB layout or redesign thereof to improve EMC performance.

### SUMMARY

A conventional approach to mitigating equipment EMI involves enclosing the operational components within a single metal housing, analogous to a Faraday enclosure. However, electromagnetic noise (caused by unintended conducted and radiated emissions) often leaks through apertures, seams, gaps, vents, slots, or other discontinuities in the single housing, especially when the underlying equipment is operating at high voltages, presenting a significant challenge in maintaining an EMC-compliant system. This electromagnetic noise leakage becomes significant when the single housing contains removable panels or modular parts that allow electromagnetic noise to escape, thereby compromising EMI shielding. Moreover, these discontinuities can act as slot antennae, making the housing itself a secondary source of EMI. On the other hand, the single housing without openings can (i) significantly block or limit intended radiofrequency (RF) signals required for remote communication, (ii) impede effective cooling of the enclosed components, and (iii) interfere with electrical connections to other distributed external components such as the functional unit (or load unit). Additionally, wires, cables, and/or harnesses entering and exiting the single housing, as well as gaps in the equipment chassis, can unintentionally act as radiating antennas, radiating electromagnetic noise that can cause EMC failure.

Another common approach to EMI shielding involves a first housing fastened to a second housing to create a shielding cavity between them for electromagnetic suppression. Inside the shielding cavity, an isolation plate is mechanically connected to the housings. The isolation plate divides the shielding cavity into a high-voltage area and a low-voltage area, electromagnetically isolated from each other. The second housing has a high-voltage interface on the side corresponding to the high-voltage isolation area and a low-voltage interface positioned on the side corresponding to the low-voltage isolation area. While this configuration may suppress spatial radiation and conducted couplings inside the housings, the shielding cavity is susceptible to leakage of radiated emissions from the seam (i.e., joint line) of the two housings and from external cable assemblies connected to the interfaces. Moreover, gaps at the seam are typically controlled with screws, which can inadvertently vary those gaps to create slot-like leakage paths that can adversely affect shielding effectiveness. In fact, the shielding cavity typically relies on a seal between the first and second housings to prevent electromagnetic noise leakage with no provision for ventilation. This lack of ventilation openings can magnify the thermal burden, increasing the risk of system failure, especially in large ISM equipment.

The sealed housings, along with the absence of openings, can also weaken intentional RF signals for remote communication with a wireless transceiver located inside the shielding cavity, thereby making the traditional configuration incompatible with intentional RF radiating components for wireless communication. Further, dividing the shielding cavity into two smaller cavities can create distinct resonances in the high-voltage and low-voltage areas. This change in resonance can unpredictably alter the electromagnetic noise, which, if increased, could leak through the housings. Alternatively, EMI filters are placed inside the enclosure, such as the first and the second housings. EMI filters, such as filter capacitors, are generally disposed at the circuit or PCB level to filter specific frequencies or frequency bands and provide impedance matching around communication paths inside the housings. However, introducing additional components inside the housings can degrade signal integrity, introduce parasitic capacitance, and increase system complexity and costs.

A further technique to reduce EMI involves lowering the equipment's clock frequency or spreading the energy across a broader frequency range. While these frequency-based techniques may reduce the peak spectral density at specific frequencies, they do not eliminate the underlying noise-generation mechanisms (e.g., common-mode currents or high rates of voltage or current transitions) and therefore do not reliably reduce the total radiated emissions. Additionally, lowering the clock frequency is not feasible in systems that rely on fixed-frequency operation, require high computational throughput, and/or are tightly constrained by timing performance in equipment used for real-time applications or data-intensive processes, where high-speed wired or wireless communication is critical.

Embodiments of the present application respond to the unmet needs and problems in the state-of-the art approaches. One embodiment of the present application includes an apparatus for improving electromagnetic compatibility of an equipment. The apparatus may include a first housing, a second housing, and a third housing. The first housing may define a first interior volume and a first plurality of openings to the first interior volume. The first plurality of openings may include a first side opening and a first lateral opening. The first housing may include a first outer plate mounted to a first panel carrying a first group of components and a first inner plate including the first lateral opening. The second housing may define a second interior volume and a second plurality of openings to the second interior volume. The second plurality of openings may include a second side opening and a second lateral opening. The second housing may include a second outer plate mounted to a second panel carrying a second group of components, and a second inner plate including the second lateral opening. The second inner plate may be mounted in contact with the first inner plate with the second lateral opening axially aligned with the first lateral opening. The third housing may define a third interior volume and a third plurality of openings to the third interior volume. The third plurality of openings may include a first set of openings and a second set of openings. The third housing may be mounted on both the first housing and the second housing with the first set of openings axially aligned with the first side opening and the second set of openings axially aligned with the second side opening.

Another embodiment of the present application includes a system for improving electromagnetic compatibility of an equipment. The system may include a first apparatus and a second apparatus. The first apparatus may include a first housing, a second housing, and a third housing. The first housing may define a first interior volume and a first plurality of openings to the first interior volume. The first plurality of openings may include a first side opening and a first lateral opening. The first housing may include a first outer plate mounted to a first panel carrying a first group of components and a first inner plate including the first lateral opening. The second housing may define a second interior volume and a second plurality of openings to the second interior volume. The second plurality of openings may include a second side opening and a second lateral opening. The second housing may include a second outer plate mounted to a second panel carrying a second group of components and a second inner plate including the second lateral opening. The second inner plate may be mounted in contact with the first inner plate with the second lateral opening axially aligned with the first lateral opening. The third housing may define a third interior volume and a third plurality of openings to the third interior volume. The third plurality of openings may include a first set of openings and a second set of openings. The third housing may be mounted on both the first housing and the second housing with the first set of openings axially aligned with the first side opening and the second set of openings axially aligned with the second side opening. The second apparatus may be operably connected to the first apparatus. The second apparatus may include a fourth housing defining a fourth interior volume and at least one opening to the fourth interior volume. The fourth housing may include a functional unit mounted thereto that may be electrically connected to at least one of the first group of components and the second group of components.

The above summary of exemplary embodiments is not intended to describe each disclosed embodiment or every implementation of the present application. Other and further aspects and features of the disclosure would be evident from reading the following detailed description of the embodiments, which are intended to illustrate, not limit, the present application.

### BRIEF DESCRIPTION OF DRAWINGS

The illustrated embodiments of the present application would be best understood with reference to the drawings, wherein like parts are designated by like numerals throughout. The following description is intended only by way of example, and simply illustrates certain selected embodiments of systems, apparatuses, and related processes that are consistent with the subject matter as claimed herein.

FIG. 1 is a rear perspective view of a robot implementing an exemplary EMC system, according to an embodiment of the present application.

FIG. 2 is a front perspective view of a chassis for the robot of FIG. 1, according to an embodiment of the present application.

FIG. 3 is a perspective view of an exemplary EMC apparatus for the EMC system of FIG. 1, according to an embodiment of the present application.

FIG. 4 is a schematic of a typical assembly of functional units for driving the robot of FIG. 1.

FIG. 5 illustrates tables including regulatory limits for unintended radiated emissions and unintended conducted emissions.

FIGS. 6-11 are schematics illustrating construction of an exemplary first EMC housing for the EMC apparatus of FIG. 3, according to an embodiment of the present application.

FIGS. 12-17 are schematics illustrating construction of an exemplary second EMC housing for the EMC apparatus of FIG. 3, according to an embodiment of the present application.

FIG. 18 is a schematic illustrating exemplary interconnection between the first EMC housing of FIG. 10 and the second EMC housing of FIG. 16 to create exemplary lower housings, according to an embodiment of the present application.

FIGS. 19-26 are schematics illustrating construction of an exemplary third EMC housing for the EMC apparatus of FIG. 3, according to an embodiment of the present application.

FIG. 27 is a schematic illustrating an exemplary interconnection between the third EMC housing of FIG. 26 and the lower housings of FIG. 18 to create the EMC apparatus of FIG. 3, according to an embodiment of the present application.

FIGS. 28-29 are rear perspective views of an exemplary load unit in a closed configuration for communication with the EMC system of FIG. 1, according to an embodiment of the present application.

FIG. 30 is a front perspective view of the load unit of FIG. 28 in the closed configuration, according to an embodiment of the present application.

FIG. 31 is a front perspective view of the load unit of FIG. 30 in an open configuration, according to an embodiment of the present application.

FIG. 32 is a schematic illustrating an exemplary mounting of the load unit of FIG. 28 and the EMC apparatus of FIG. 3 on the chassis of FIG. 2, according to an embodiment of the present application.

FIG. 33 is an exemplary graph illustrating a measured level of unintended radiated emissions from a robot implementing a traditional arrangement of FIG. 4 for the underlying functional units without the EMC system of FIG. 1, according to an embodiment of the present application.

FIG. 34 is an exemplary graph illustrating a measured level of unintended radiated emissions from the robot with the EMC system of FIG. 1, according to an embodiment of the present application.

FIG. 35 is an exemplary graph illustrating a measured level of unintended conducted emissions on the hot AC supply line connected to the robot implementing the EMC system of FIG. 1, according to an embodiment of the present application.

FIG. 36 is an exemplary graph illustrating a measured level of unintended conducted emissions on the neutral AC supply line connected to the robot implementing the EMC system of FIG. 1, according to an embodiment of the present application.

### DETAILED DESCRIPTION

The following detailed description is provided with reference to the drawings herein. Exemplary embodiments are provided as illustrative examples so as to enable those skilled in the art to practice the disclosure. It will be appreciated that further variations of the concepts and embodiments disclosed herein can be contemplated. The examples of the present application described herein may be used together in different combinations. In the following description, details are set forth in order to provide an understanding of the present application. It will be readily apparent, however, that the present application may be practiced without limitation to any or all these details. Also, throughout the present application, the terms “a” and “an” are intended to denote at least one of a particular element. The terms “a” and “an” may also denote more than one of a particular element. As used herein, the term “includes” means includes but not limited to, the term “including” means including but not limited to. The term “based on” means based at least in part on, the term “based upon” means based at least in part upon, and the term “such as” means such as but not limited to. The terms “approximately” and “about” mean a variation of up to +/−20% in a stated number or in an intended value (or a measured value) of a stated parameter. The term “substantially” means a deviation of up to +/−20% from an expected value or a target value of an associated parameter.

Further, where certain elements of the present application can be partially or fully implemented using known components, only those portions of such known components that are necessary for an understanding of the present application would be described, and detailed descriptions of other portions of such known components are omitted so as not to obscure the invention(s). In the present application, an embodiment showing a singular component should not be considered limiting; rather, the present application is intended to encompass other embodiments including a plurality of the same or similar component, and vice-versa, unless explicitly stated otherwise herein. Moreover, the applicant does not intend for any term in the present application to be ascribed an uncommon or special meaning unless explicitly set forth as such. The present application also encompasses present and future known equivalents to the components and materials referred to herein.

### Non-Limiting Definitions

Definitions of one or more terms that will be used in this disclosure are described below without limitations. For a person skilled in the art, it is understood that the definitions are provided only for the sake of clarity and are intended to include more examples than just provided below.

A term “Conducted Emission” is used in the present application in the context of its broadest definition. The conducted emission may refer to RF energy or signals conducted onto a physical conductive path, e.g., at an input terminal of the equipment.

A term “Radiated Emission” is used in the present application in the context of its broadest definition. The radiated emission may refer to RF energy or signals emitted through free space as electromagnetic waves from the equipment and its associated components.

A term “Electrical Connector” is used in the present application in the context of its broadest definition. The electrical connector may refer to a physical conductive structure that allows electrical power and/or signals to pass therethrough, providing electrical connectivity between components and functional units. Examples of the electrical connector include, but are not limited to, wire, cable, harness, or any suitable combinations thereof.

A term “Functional Unit” is used in the present application in the context of its broadest definition. The functional unit may refer to an assembly of one or more electrical, electronic, and/or electromechanical components, circuits, and/or devices configured to collectively perform a predetermined function. The functional unit may correspond to a set of one or more of the same or different types of components and/or functional units. In some instances, the functional unit may operate in tandem with, or upon being triggered by, another functional unit to perform the predetermined function. In further instances, the functional unit may represent or include an electrical load.

The term “Quasi-peak Value” is used in the present application in the context of its broadest definition. The quasi-peak value may refer to a level of electromagnetic emissions measured using a detector that weights an emission signal according to both signal amplitude and signal pulse repetition rate. The quasi-peak value may indicate a relative likelihood of an electromagnetic emission causing an objectionable interference to signal receivers. The quasi-peak value provides a measure not only of how high the emission signal amplitude (or the noise amplitude) is, but also of how often the noise occurs. Unlike a signal peak value, which may indicate only the maximum instantaneous amplitude of electromagnetic emissions, the quasi-peak value may represent the time-weighted impact of the electromagnetic emissions.

### Exemplary Embodiments

Embodiments of the present application are disclosed in the context of systems, apparatuses, kits, and related methods of use and assembly for improving electromagnetic compatibility (EMC) of an equipment, such as robots. However, one having ordinary skill in the art would understand that the concepts described herein may be implemented for various other purposes, including, but not limited to, (a) structured routing and management of electrical connectors; (b) distribution and/or consolidation of electrical and mechanical interfaces; (c) physical, electrical, and/or electromagnetic separation between functional units; (d) placement, isolation, and management of high-voltage units (e.g., load units) connected to the equipment; and (e) modulation of shape, size, and/or center of gravity of the equipment to improve spatial mobility, portability, and footprint as per intended application.

The concepts and embodiments are described with reference to a robot 102; however, the disclosure is not limited to robots and may be applied to any EMC-sensitive electrical, electronic, and/or electromechanical systems. The robot 102 may be mobile or stationary during operation. The robot 102 may represent or include a machine, or vice versa. In some instances, the robot 102 may represent or include a vehicle, or vice versa. Other instances may include the robot 102, or the vehicle, comprising a dedicated apparatus serving a predefined function. The dedicated apparatus may represent or include a portable unit or a handheld unit, or both, which may be permanently attached or removably secured to the robot 102. Examples of the dedicated apparatus may include, but are not limited to, a robotic arm, a power supply unit such as a battery, a storage unit, a transportation unit, a germicidal unit, and a receptacle or stowing unit, or any suitable combinations thereof. The robot 102 or the dedicated apparatus may be configured to perform one or more functions including, but not limited to, cleaning, disinfection, transportation, palletizing, hauling, grabbing, lifting, elevating, hoisting, medical surgery, geological mining, display of video or images, provide audio and haptic output or feedback, and transmission or receipt of intended signals or energy, such as data, power, or control signals.

Aspects of the embodiments and concepts disclosed herein, including any variants thereof, may advantageously (1) reduce unintended conducted emissions propagated along electrical connectors from the equipment onto AC mains and/or an associated remote equipment; (2) minimize unintended/unwanted radiated emissions from the equipment to external environment; (3) reduce unintended electromagnetic coupling between functional units and/or underlying components; (4) prevent degradation of intentional signals to and from RF wireless unit; (5) improve RF grounding of EMC-compliant housings; (6) provide modular system and apparatus for an EMC-compliant implementation, troubleshooting, repair, and maintenance of the robot and related electromagnetic shielding components; (7) improve vent configuration for a controlled leakage to reduce thermal burden and unintended electromagnetic emissions (or noise) while improving wireless remote communication to/from the equipment; (8) improve structural continuity of EMC-compliant housings for various functional units; (9) reduce the risk of task-control malfunction due to noise coupling; and (10) provide retrofittable kits to (a) implement one or more Faraday enclosures and/or (b) modularly shield and/or isolate one or more functional units and/or high-voltage load units associated with the equipment such as the robot 102.

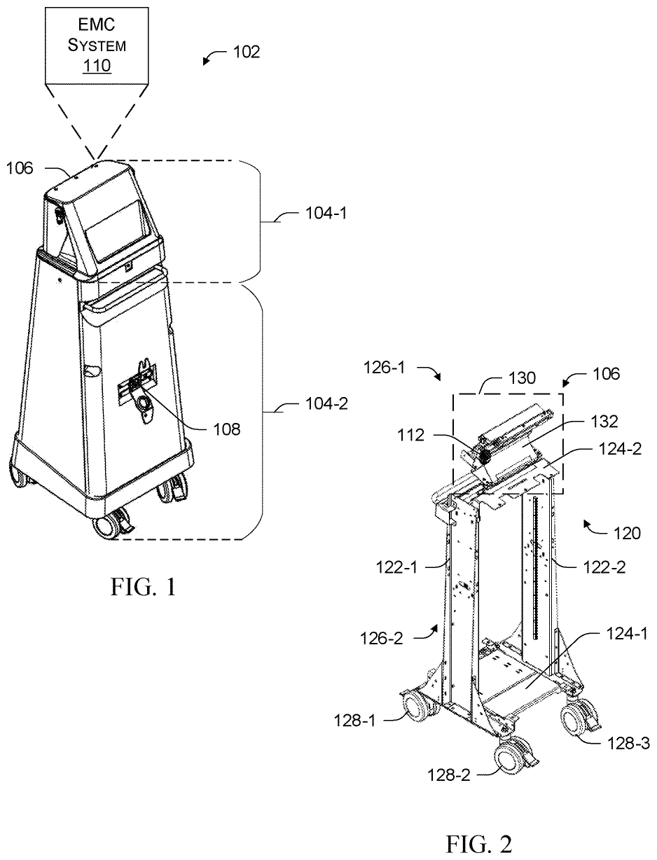

In one embodiment, the robot 102 may be configured to perform surface disinfection; however, other suitable types of robots such as those mentioned above may be contemplated. As illustrated in FIG. 1, the robot 102 includes a first section 104-1 and a second section 104-2 (hereinafter collectively referred to as robot sections 104). The first section 104-1 may be disposed over the second section 104-2, or vice versa. The first section 104-1 may include a load unit 106; however, some examples may include the load unit 106 being at least in-part being disposed in the second section 104-2. The load unit 106 may be driven by one or more functional units, discussed below in greater detail. The functional units may be disposed in the second section 104-2; however, some examples may include some of the functional units being disposed, wholly or at least in-part, in the first section 104-1.

The load unit 106 may include a powered unit or a non-powered unit, or both, depending on its intended function or that of the robot 102. The load unit 106 may represent or include a high-voltage unit or a suitable combination of high-voltage and low-voltage units. By way of example, it may be understood that high-voltage may refer to a voltage level of more than approximately 24V and low-voltage may refer to a voltage level of approximately 24V or less; however, such differentiation may change depending on a type of intended or predefined function of the load unit 106 or that of the robot 102. In some examples, the load unit 106 may include or, at least in part, operate as a high-voltage source. Other examples may include the load unit 106 being driven by a high-voltage unit, or vice versa. The high-voltage source may be located in the second section 104-2; however, some examples may include the high-voltage source being at least in-part disposed in the first section 104-1 of the robot 102. In the illustrated example, the robot 102 may include a power port 108 located in the second section 104-2. The power port 108 may be connected to a power supply (e.g., AC supply) and operate as a high-voltage source. The power port 108 may operate in communication with an EMC system 110, discussed below in greater detail. The EMC system 110, or parts thereof, may be configured to drive the load unit 106 while improving the electromagnetic compatibility of the robot 102 during operation. Further examples may include the high-voltage source being located external to the robot 102 (or the load unit 106) and connected to the power port 108. Other examples of the load unit 106 may include, but are not limited to, actuators, motors, laser systems, plasma cutters, electromagnetic grippers, robotic and/or articulated arms, hydraulic pumps, and energy transceivers.

In the illustrated embodiment of FIG. 1, the load unit 106 includes a germicidal source 112, discussed below in greater detail. In some examples, the germicidal source 112 may represent or include a set of multiple germicidal sources. The germicidal sources, such as the germicidal source 112, may be configured to provide the same or different types of germicide based on an intended target or ambient recipient. The germicide, or a source thereof, may be selected and operated by (e.g., a controller of) the robot 102, either independently or in communication with a remote device (not shown), based on an intended effect (e.g., surface or fluid disinfection) or an intended function such as those mentioned above. Examples of the germicide may include, but are not limited to, ultraviolet (UV) light, intended energies, and complementing agents, or any suitable combinations thereof. Examples of such intended energies may include, but are not limited to, radio, microwave, x-ray, infrared, visible light, or any other specific wavelength or a group of wavelengths in the electromagnetic spectrum. Examples of the complementing agents may include, but are not limited to, chemical agents (e.g., alcohols, aldehydes, oxidizing agents, naturally occurring or modified compounds, etc.), physical agents (e.g., heat, pressure, vibration, sound, radiation, plasma, electricity, etc.), and biological agents (e.g., living organisms, plants or plant products, assistive-pathogens, organic residues, etc.). Further, the germicidal source 112 may include a radiation source, a non-radiation source, or a combination thereof. Examples of the radiation source may include, but are not limited to, an ultraviolet (UV) source (e.g., Xenon pulsed UV lamp, continuous UV lamp, etc.) and an electron-beam generator. Examples of the non-radiation source may include, but are not limited to, an ozone generator and a fumigation generator using a chemical disinfectant such as formaldehyde, ethylene oxide, chlorine dioxide, methyl bromide, and sulfur dioxide, or any combinations thereof. In further examples, the load unit 106 or a part thereof may be configured to rotate or move during robot operation.

Further, the robot 102, including parts the EMC system 110, may be configured to operate, or cease to operate, in communication with the remote device over a wired or wireless network. The remote device may represent or include a computing device, a computer readable medium, a network device, a computer peripheral device, or any suitable combinations thereof. Examples of the computing device include, but are not limited to, a desktop computer, a personal digital assistant (PDA), a server, a mainframe computer, a mobile computing device (e.g., mobile phone, laptop, tablet, etc.), and an internet appliance (e.g., a modem, a wireless access point, a router, a base station, a gateway, etc.). In some examples, the remote device may include another robot similar to the robot 102 as described in the present application. The robot 102, either independently or in communication with the remote device, may have video, voice, or data communication and storage capabilities. For example, the robot 102, or the remote device, may include an imaging device (e.g., camera, printer, scanner, medical imaging device/system, etc.), an audio device (e.g., microphone, audio player, audio recorder, telephone, speaker, etc.), a video device (e.g., monitor/interactive display unit, image projector, television, video recorder, etc.), sensors, keyboard or stylus, magnetic or barcode readers, biometric scanners, or any other types of hardware commensurate with predefined or dynamically defined robot 102 functions, or otherwise intended, including those mentioned above. The robot 102 may include various components including the novel EMC system 110 mounted to a chassis 120 for support and stability.

As illustrated in FIG. 2, the chassis 120 may serve as a frame to mount one or more functional units and components of the robot 102. In the illustrated embodiment, the chassis 120 includes a first column 122-1, a second column 122-2, a base platform 124-1, and a top platform 124-2. The first column 122-1 and the second column 122-2 (hereinafter collectively referred to as support columns 122) may be secured to the base platform 124-1. In some examples, the support columns 122 may be integrated or replaced by a single column. The support columns 122 may have similar or different geometries and dimensions for the ease of construction, center of gravity, intended stability of the chassis 120. The support columns 122 may be configured to mount one or more of the same or different types of components, assemblies, functional units, devices, and systems such as the EMC system 110. The support columns 122 may be perpendicular to the base platform 124-1; however, some examples may include either, or both, of the support columns 122 being tilted at an angle greater than or less than 90 degrees relative to the base platform 124-1 and/or the top platform 124-2 (hereinafter collectively referred to as chassis platforms 124).

The chassis 120 may include an upper section 126-1 and a lower section 126-2 (hereinafter collectively referred to as chassis sections 126). The upper section 126-1 may include the top platform 124-2 and the lower section 126-2 may include the base platform 124-1; however, some examples may include both the chassis platforms 124 disposed in the upper section 126-1 or in the lower section 126-2. Further, the top platform 124-2 may be located over and/or opposite to the base platform 124-1; however, some examples may include the top platform 124-2 being disposed lateral to the base platform 124-1, or in a plane excluding the base platform 124-1. Further examples may include the chassis platforms 124 having a separator (not shown), such as a housing or a supporting base, between them to support the EMC system 110. In some instances, the separator may be integrated with or supported by the base platform 124-1 or the top platform 124-2. Other examples may include either or both the chassis platforms 124 being rotatable about a horizontal axis and/or a vertical axis of the chassis 120 or the robot 102. For instance, the top platform 124-2 may be configured to rotate relative to the base platform 124-1, or vice versa. The vertical axis may include one of the support columns 122. The horizontal axis may be perpendicular to the vertical axis or the support columns 122. The horizontal axis may include at least one of the base platform 124-1, top platform 124-2, or the separator.

As illustrated in FIG. 2, the lower section 126-2 may include a mobility unit connected thereto. The mobility unit may assist in moving the chassis 120 and the robot 102 spatially from one position to another. The mobility unit may be motorized or non-motorized. The mobility unit may be automated or configurable for manual operation. For example, the mobility unit may move the chassis 120 and the robot 102 when manually pushed or pulled by an operator. In the illustrated embodiment of FIG. 2, the mobility unit is represented as wheel 128-1, 128-2, and 128-3 (collectively wheels 128). One having ordinary skill in the art would understand that any suitable types of wheels known in the art, related art, or developed later may be implemented including, but not limited to, omnidirectional wheels and caster wheels, depending on a surface and/or an ambient environment where the chassis 120, and hence the robot 102, is intended to be moved. The wheels 128 may be attached to the base platform 124-1 or the support columns 122. In another embodiment, the mobility unit may be adapted as an autonomous vehicle (with such wheels 128) configured to navigate the chassis 120, and the robot 102, autonomously. Other embodiments may include the autonomous vehicle (not shown) being further configured to move the chassis 120 (or the robot 102) in response to a control signal from the remote device. For example, the autonomous vehicle may include a local control unit (not shown), sensors, and one or more wheels mounted thereto. The local control unit may operate in communication with a controller of the robot 102 and/or the remote device to control and direct various functions of the autonomous vehicle. Further, the autonomous vehicle may include a support platform (not shown) configured to support or mount the base platform 124-1 (or the chassis 120) thereto; however, some examples may include the support platform defining the base platform 124-1. The support platform (or the base platform 124-1) may receive or support one or more functional units and components of the robot 102.

Further, the upper section 126-1 of the chassis 120 may include the load unit 106; however, some examples may include the load unit 106, at least in-part, being disposed in the lower section 126-2 of the chassis 120. In one embodiment, the load unit 106 may include a germicidal assembly 130 mounted to the chassis 120. The germicidal assembly 130 may include the germicidal source 112 such as those mentioned above. In the illustrated example of FIG. 2, the germicidal source 112 is a high-voltage pulsed UV lamp emitting pulsed UV light; however, any other suitable types of one or more germicidal sources may be additionally or alternatively be implemented to provide one or more types of germicide, such as those mentioned above. The germicidal assembly 130 may further include a reflector 132 to assist in directing the germicide such as the UV light toward a target direction or a target object. The reflector 132 (or the germicidal assembly 130) may be secured to the top platform 124-2 and/or the support columns 122 for stability and support. Further, the germicidal source 112 may serve as a primary load based on a primary function, e.g., surface disinfection, of the robot 102. One having ordinary skill in the art would understand that the primary load may differ depending on a primary function in other types of load units and/or robots, such as those mentioned above. The primary load may be driven by a group of one or more functional units in the EMC system 110.

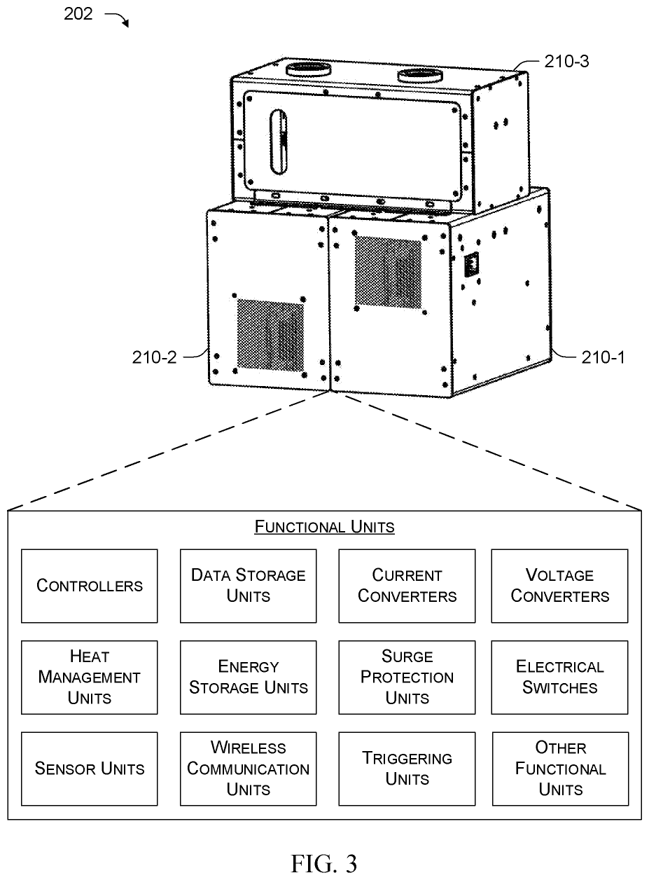

In one embodiment, as illustrated in FIG. 3, the EMC system 110 may be configured to enclose various types of functional units to prevent or reduce the unintended electromagnetic emissions therefrom from being released into the external environment. These various types of functional units may collectively, or in set combinations, drive the primary load and/or the load unit 106. These functional units may power and/or control the load unit 106 or an apparatus including the primary load. Examples of the such types of functional units may include, but are not limited to, controller, current converter, voltage converter, heat management unit, energy storage unit, data storage unit, energy surge protection unit, electrical switch, sensor unit, wireless communication unit, and triggering unit.

The controller may correspond to a functional unit configured to control predefined or dynamically defined functions and movements of the robot 102. In some instances, the controller may additionally control or coordinate between other functional units and/or underlying components. The controller may include or be implemented by way of a single device (e.g., a computing device, a processor or an electronic storage device) or a combination of multiple devices. The controller may operate in communication with a software product to control one or more aspects of the robot 102. The controller may be implemented in hardware or a suitable combination of hardware and software. For example, the controller may be embedded on a printed circuit board (PCB). The controller may represent or include microprocessors, microcomputers, microcontrollers, digital signal processors, central processing units, state machines, logic circuits, and/or any devices that may manipulate received signals based on operational instructions. The controller may additionally include, or operate in communication with, one or more interfaces such as software interfaces (e.g., application programming interfaces, a graphical user interfaces, software ports, network sockets, etc.); hardware interfaces (e.g., electrical connectors, physical connection adaptors, plugs, hardware ports and sockets, etc.); or both. Among other capabilities, the controller may fetch and execute computer readable instructions stored in a data storage unit.

The data storage unit may correspond to a functional unit configured to store, manage, and/or process data. The data storage unit may include any suitable computer readable medium such as a volatile memory (e.g., RAM, cache memory, etc.) and a non-volatile memory (e.g., flash memory, solid state drive etc.). In some instances, the data storage unit may further include one or more databases, which may be sub-divided into further databases for storing electronic files and data. Further, the current converter may correspond to a functional unit configured to convert, sense, regulate, or condition electrical current. For instance, the current converter may (i) convert alternating current (AC) into direct current (DC), or vice versa, (ii) convert electrical current into a measurable voltage signal, or (iii) regulate electrical current to maintain a predefined value or within a preset range, or any suitable combinations thereof. Examples of the current converter may include, but are not limited to, a rectifier circuit, a shunt resistor, a transimpedance amplifier, or a current limiter, or any suitable combinations thereof.

The voltage converter may correspond to a functional unit configured to convert, regulate, or condition electrical voltage. For instance, the voltage converter may (i) convert AC voltage into DC voltage, or vice versa, (ii) increase or decrease an input voltage, or (iii) modify an amplitude or magnitude of an AC or DC voltage signal, or any suitable combinations thereof. Examples of the voltage converter may include, but are not limited to, a buck converter, a boost converter, a buck-boost converter, a step-up voltage transformer, step-down voltage transformer, voltage inverters, or a voltage regulator, or any suitable combinations thereof. The heat management unit may correspond to a functional unit configured to remove, dissipate, or distribute heat around or generated by functional units or operating components within an equipment such as the robot 102. Examples of the heat management unit may include, but are not limited to, heat sinks, cooling fans, liquid cooling systems, or thermal plates, or any suitable combinations thereof. Further, the energy storage unit may correspond to a functional unit configured to store electrical energy. Examples of the energy storage unit may include, but are not limited to, batteries, capacitors, capacitor banks, supercapacitors, superconducting magnetic energy storage units, or any suitable combinations thereof. The energy surge protection unit may correspond to a functional unit configured to protect other functional units including associated circuits and components from voltage spikes or current surges. Examples of the energy surge protection unit may include, but are not limited to, varistors, transient voltage suppression (TVS) diodes, electrical fuses, circuit breakers, or any suitable combinations thereof. The electrical switch may correspond to a functional unit configured to operate as an electrical gateway between a power supply source and intended functional units and/or associated components. Examples of the electrical switch may include, but are not limited to, solid-state relays, contractors, MOSFET switches, circuit breakers, RF switches, analog multiplexers, or any other high-voltage or low-voltage switching components, or any suitable combinations thereof.

The sensor unit may correspond to a functional unit configured to detect physical quantities (e.g., temperature, pressure, voltage, current, etc.) and convert them into electrical signals. The sensor unit may include a set of one or more sensors and associated circuits. Examples of the sensors may include, but are not limited to, temperature sensors, position sensors, pressure sensors, motion and position sensors (e.g., rotary encoders, non-rotary encoders, hall-effect sensors, etc.), imaging sensors, humidity sensors, radiation sensors, air quality sensors, electrical sensors (e.g., voltage sensors, current sensors, power sensors, etc.), acoustic sensors, vibration sensors, accelerometer, gyroscope, magnetometer, or optical sensors, or any suitable combinations thereof. Further, the wireless communication unit may correspond to a functional unit configured to transmit and/or receive radiofrequency (RF) signals. Examples of the wireless communication unit may include, but are not limited to, Wi-Fi® unit, Bluetooth® unit, RF transceiver, or cellular modem, or any combinations thereof. The triggering unit may correspond to a functional unit configured to trigger another functional unit or associated component when a predefined or dynamically defined condition is met. In some instances, the triggering unit may represent or include a controller, or vice versa. The triggering unit may provide a trigger signal either periodically or in response to another signal, e.g., from another functional unit or a remote device such as those mentioned above. Examples of the triggering unit may include, but are not limited to, a pulse trigger circuit, interrupt generator, comparator or related trigger circuit, or any suitable combinations thereof.

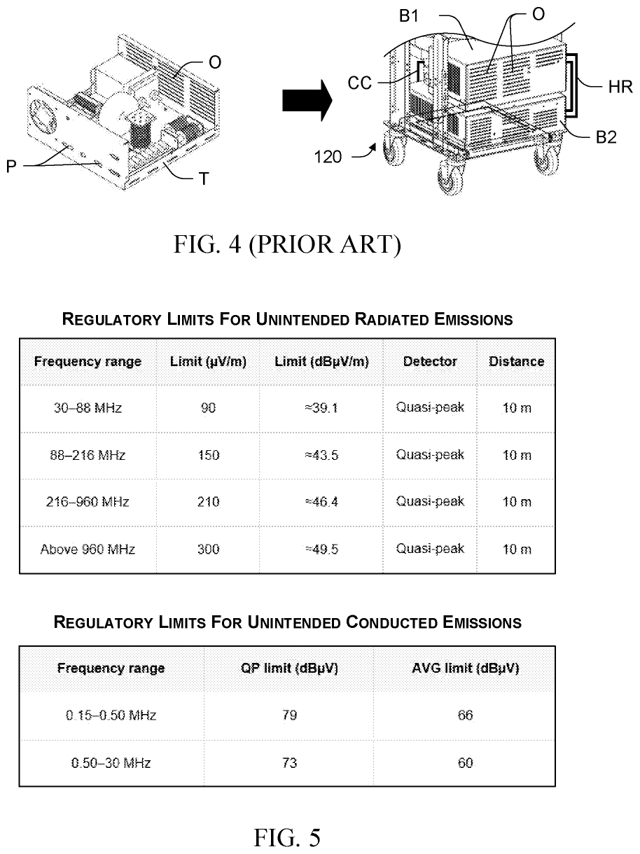

In a typical arrangement, as illustrated in FIG. 4, the functional units are generally laid out together openly on a horizontal platform T. Since many of these functional units perform rapid current and voltage switching, which increases electric field strength and/or displacement currents through parasitic capacitances, an electromagnetic coupling between the underlying operational components often causes unintended conducted emissions and unintended radiated emissions (hereinafter collectively referred to as unintended electromagnetic emissions) beyond their respective permissible limits set by regulatory standards such as those shown in FIG. 5. The platform T, including the underlying functional units, is encased in a traditional box B1. This box B1 typically has removable panels and open seams that introduce variability in electrical bonding and structural continuity, which allows unintended radiated emissions to leak from the box B1 and exceed the permissible limits.

Further, the box B1 usually has openings O that are typically spread across most sides of the box B1. Although such a large spread of these openings O assists in heat dissipation and intended RF signals to pass through for remote communication, variable sizes and scattered design of these openings O cause them to act as slot antennas, further reducing the effectiveness of the traditional box B1 in containing these unintended electromagnetic emissions within the permissible limits. Moreover, the box B1 typically has external ports P for electrical connections with external components and equipment. For example, the box B1 is generally connected to another box B2 via external cables CC and harnesses HR outside the boxes B1 and B2. However, each of these external, exposed cables CC and/or harness HR act as radiating antennas to increase the unintended radiated emissions and unintended conducted emissions beyond the permissible limits.

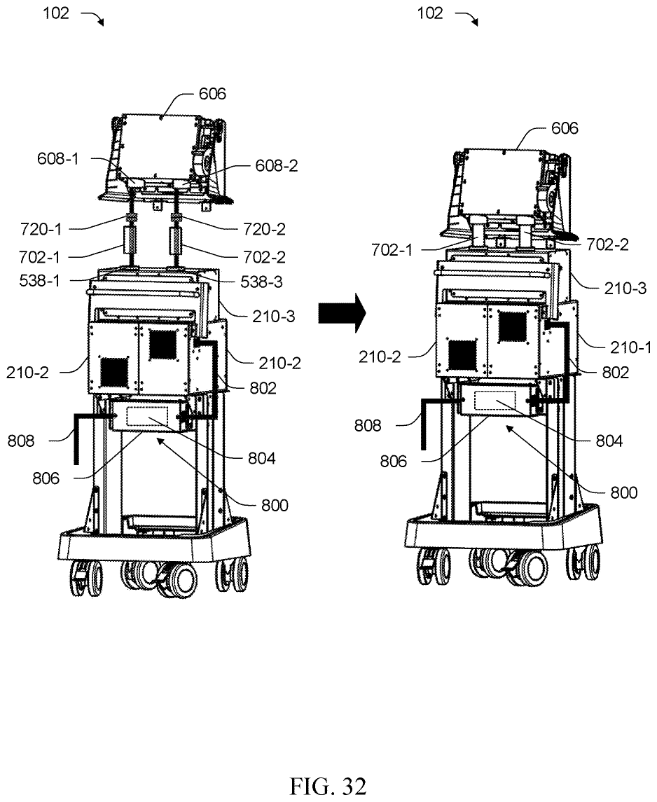

Unlike the traditional box B1 and related typical layout and interconnections of functional units, the novel EMC system 110 addresses drawbacks in the prior art systems to improve the electromagnetic compatibility of an equipment such as the robot 102. In one embodiment, the EMC system 110 includes an assembly of one or more modular apparatuses that can be retrofitted in the robot 102 without requiring modifications to the existing design, dimensions, and/or layouts of circuit PCBs, the chassis 120, and the robot 102. For example, as illustrated in FIG. 3, the EMC system 110 includes a first EMC apparatus 202 and a second EMC apparatus 204 (shown in FIG. 29). In some examples, the EMC system 110 may further include a third EMC apparatus 800 (shown in FIG. 32). The first EMC apparatus 202 may include three distinct housings, namely, a first EMC housing 210-1, a second EMC housing 210-2, and a third EMC housing 210-3 (hereinafter collectively referred to as EMC housings 210). Each of the EMC housings 210 may be constructed to operate as Faraday enclosures. The EMC housings 210, individually and collectively, may have a footprint or a geometry relatively smaller than that of the chassis 120, a spacing between the support columns 122, and the robot 102.

In the first EMC apparatus 202, the EMC housings 210 may be constructed individually to provide them as part of a retrofittable kit for improving EMC and then assembled together for or on an equipment such as the robot 102. The EMC housings 210 may be individually constructed in a manner that (1) prevents or reduces access to an interior portion of each individual EMC housing after construction, (2) provides electromagnetic shielding to the underlying functional units from external EMI, (3) prevents or reduces electromagnetic coupling (or electromagnetic noise) between functional units across different EMC housings 210, and (4) reduces leakage or release of unintended electromagnetic emissions (i.e., unwanted noise) outside the robot 102 or to the external environment.

Each of the EMC housings 210 may be disposed in the same or different planes relative to the horizontal axis of the robot 102. For example, at least two of the EMC housings 210, such as the first EMC housing 210-1 and the second EMC housing 210-2 (hereinafter collectively referred to as lower housings), may be disposed in the same horizontal plane relative to the third EMC housing 210-3, where the horizontal plane may be parallel to the horizontal axis. The third EMC housing 210-3 may be stacked over and in contact with both the lower housings. Some examples may include the third EMC housing 210-3 mounted in contact with only one of the lower housings. Other examples may include any combination of the EMC housings 210 disposed lateral to each other in the same horizontal plane that is parallel to the horizontal axis of the robot 102, or in the same vertical plane that is parallel to the vertical axis of the robot 102. Such mounting of each of the electrically-conductive EMC housings 210 in contact with each other may assist in electrical grounding of the whole first EMC apparatus 202 using a single grounding point; however, such electrical grounding may still be done at multiple points in the EMC housings. Similarly, all other electrically-conductive housings, panels, brackets, and/or conduits in contact with the EMC housings 210 may automatically become electrically grounded at the single grounding point, though multiple points on these parts may still be electrically grounded if desired. Each of the EMC housings 210 may enclose the same or different number and types of functional units, such as those mentioned above. As such, the functional units responsible for driving the load unit 106 may be distributed, separated, and enclosed across different EMC housings 210 to reduce the total unintended electromagnetic emissions from the first EMC apparatus 202, and the robot 102, to below the permissible limits. The number of EMC housings 210 may depend on the number and types of functional units, which either individually or in combination with other functional units, generate unintended electromagnetic emissions in the regulatory frequency ranges beyond the corresponding regulatory permissible limits, illustrated in FIG. 5, during the robot operation.

Each functional unit (e.g., a main controller, a voltage transformer, etc.) and its combination with each of the directly associated functional units (e.g., a sensor unit, a triggering unit, a lamp controller, etc.) may be tested using a field strength detector to empirically assess a level of unintended electromagnetic emissions (e.g., unintended radiated emissions) from those functional units during the robot operation to drive the primary load. For example, the field strength detector may be configured to measure the unintended radiated emissions at a distance of 10 meters from different combinations of the functional units during the robot operation. Some examples may include the field strength detector being set to measure the unintended radiated emissions at other regulatory distances, such as a distance of 3 meters, from the functional units, depending on a different type of equipment including robots such as those mentioned above. In one example, the field strength detector may be configured to measure the field strength in terms of decibel-microvolts per meter and compared to the regulatory permissible limits represented as a quasi-peak value for the unintended electromagnetic emissions. In some examples, however, the field strength detector may be configured to measure (and compare with the permissible limits) the field strength in terms of average value, and/or peak value for the unintended electromagnetic emissions.

In one embodiment, if a functional unit may be determined to individually generate unintended radiated emissions having a field strength with a quasi-peak value at any frequencies within the regulatory sub-frequency ranges, namely, 30-88 MHz, 88-216 MHz, 216-960 MHz, and above 960 MHz, where that measured value (e.g., quasi-peak value) exceeds the permissible limit corresponding to any one of those sub-frequency ranges, then each such functional unit may be isolated and enclosed in a dedicated EMC housing. In some examples, such functional unit may be isolated and enclosed in a dedicated EMC housing when such quasi-peak values exceed the permissible limits corresponding to at least two of those sub-frequency ranges. Other examples may include such functional unit being isolated and enclosed in a dedicated EMC housing when such quasi-peak values exceed the permissible limits corresponding to all of those sub-frequency ranges.

In another embodiment, if a group of directly connected functional units is determined to collectively generate unintended electromagnetic emissions (e.g., unintended radiated emissions) having a field strength with a quasi-peak value at any frequencies within the regulatory sub-frequency ranges, where that measured value (e.g., quasi-peak value) exceeds the permissible limit corresponding to any one of those sub-frequency ranges, then the whole group may be isolated and enclosed in a dedicated EMC housing. In some examples, such group may be isolated and enclosed in a dedicated EMC housing when such quasi-peak values exceed the permissible limits corresponding to at least two of those sub-frequency ranges. Other examples may include such group being isolated and enclosed in a dedicated EMC housing when such quasi-peak values exceed the permissible limits corresponding to all of those sub-frequency ranges.

In a further embodiment, each of the EMC housings 210 may be configured to enclose a group of one or more intended functional units, which may collectively generate unintended radiated emissions having a field strength with quasi-peak values at any frequencies within (i.e., less than) the regulatory sub-frequency ranges, where the measured value(s) (e.g., quasi-peak values) may be less than or equal to a predefined threshold field strength value corresponding to (1) any one of those sub-frequency ranges, (2) at least two of those sub-frequency ranges, or (3) all of those sub-frequency ranges. The threshold field strength value may be represented in terms of a quasi-peak value; however, some examples may include the threshold field strength value being represented in terms of average value or peak value. The threshold field strength value may be predefined as less than the regulatory permissible limit corresponding to each of those sub-frequency ranges, shown in FIG. 5.

In order for each of the EMC housings 210 to have a group of one or more functional units where the group may generate unintended radiated emissions with a quasi-peak value less than the permissible limits, each of such functional units may be selected for the group based on one or more functional aspects of the underlying components and devices. Examples of these functional aspects may include, but are not limited to, (i) a number and types of voltage switching components or devices, (ii) a number and types of current switching components or devices, (iii) a number and types of low-voltage switching components or devices, (iv) a number and types of high-voltage switching components or devices, (v) a number and types of such electrical switching components or devices that are directly connected to each other, and (vi) a number and types of electrical connectors between the switching components or devices. Examples of these electrical connectors may include, but are not limited to, wires, cables, harnesses, vias and pads, board-to-board connectors, rails, and PCB traces, or any suitable combinations thereof. In some instances, the electrical connectors may also include electrical contacts, terminals, and solder joints.

Each of the EMC housings 210 may be made up of or include materials that are electrically conductive in nature. Examples of such electrically conductive materials may include, but are not limited to, aluminum, copper, nickel, tin-coated copper, brass, steel, silver, gold, Mu-metal (i.e., Nickel-Iron Alloy having 77% Ni, 16% Fe, 5% Cu, and 2% Mo), permalloy (i.e., Nickel-Iron Alloy having 80% Ni and 20% Fe), Nickel-coated carbon fiber, conductive polymer composites (e.g., Polyaniline, Carbon-Loaded Polymers), and silicon steel (e.g., Fe—Si alloys), or any suitable combinations thereof. In some examples, EMC housings 210 may be made up of non-conductive materials including a substantially continuous mesh of electrically conductive materials, such as those mentioned above. The electrically conductive materials may assist in the EMC housings 210 or any other housings of the EMC system 110 to operate as Faraday enclosures. Additionally, each of the housings in the EMC system 110 may be electrically grounded to further reduce or prevent the release of unintended conducted emissions therefrom to the external environment.

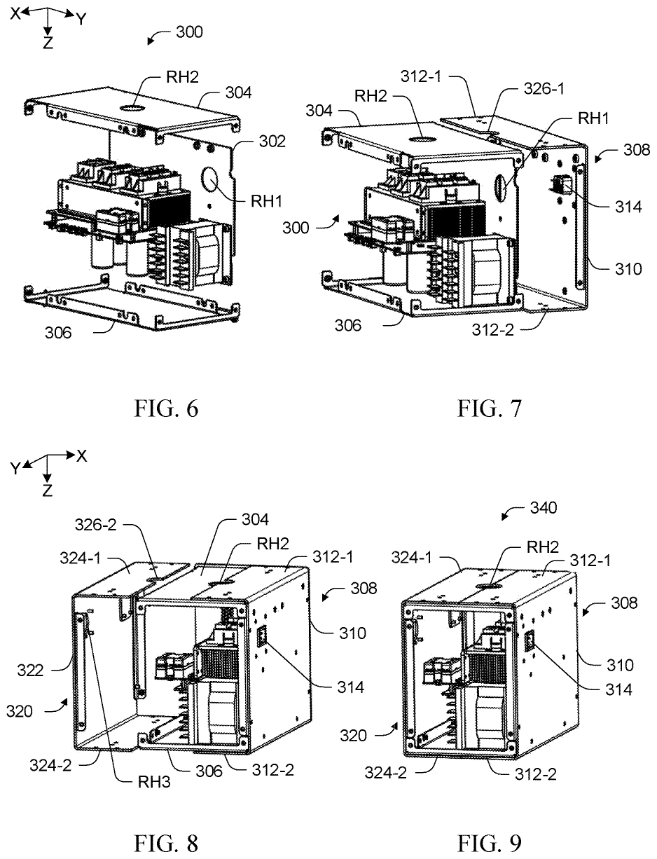

Each of the EMC housings 210 may be constructed in a modular fashion for easy assembly, repair, and maintenance. In the illustrated embodiment of FIG. 6, the first EMC housing 210-1 may include a R-lateral panel 302, a R-top panel 304, and a R-bottom panel 306. The R-lateral panel 302 may be oriented towards a first lateral side (e.g., right lateral side) of the first EMC housing 210-1. The R-lateral panel 302 may have a length (along y-axis) approximately the same as lengths (along y-axis) of both the R-top panel 304 and the R-bottom panel 306. The R-lateral panel 302 may have a vertical height (or width along z-axis) greater than a horizontal width (along x-axis) of both the R-top panel 304 and the R-bottom panel 306. The R-lateral panel 302 may provide a base for mounting an intended group of one or more functional units. The R-lateral panel 302 may be arranged parallel to the vertical axis of the chassis 120 or the robot 102. The R-lateral panel 302 may be mounted perpendicularly to edges (along y-axis) of both the R-top panel 304 and the R-bottom panel 306 to create a R-first part 300 of the first EMC housing 210-1. The R-lateral panel 302 may further include a first hole RH1 for receiving an electrical port 314. The first hole RH1 may be provided adjacent to the functional units mounted on the R-lateral panel 302.

Unlike a traditional component panel such as the platform T providing a surface parallel to the horizontal axis of the chassis 120 and/or the robot 102, a vertical arrangement of the functional units mounted to the R-lateral panel 302 may (1) provide a larger space for mounting a higher number or different combinations of intended functional units and related components due to a relatively greater width of the R-lateral panel 302, and (2) assist in better airflow around various key components (e.g., transformer, heat sinks, etc.) inside the first EMC housing 210-1 for efficient cooling during robot operation, discussed below in greater detail. In the illustrated embodiment, the R-lateral panel 302 may create a separation between the R-top panel 304 and the R-bottom panel 306 to assist in creating a first interior volume for the first EMC housing 210-1 for accommodating intended functional units. The first EMC housing 210-1 may define the first interior volume and various openings to such first interior volume. The R-top panel 304 may include a second hole RH2 to allow any suitable electrical connectors, such as those mentioned above, to pass therethrough. In one embodiment, the R-first part 300 may be mounted with a first R-cover attachment 308. As illustrated in FIG. 7, the first R-cover attachment 308 may include a R1-base plate 310, a R1-top flange 312-1, and a R1-bottom flange 312-2 (collectively referred to as R1-flanges 312). The first R-cover attachment 308 may be configured as a U-shaped bracket having both the R1-flanges 312 extending outward in the same direction at approximately 90 degrees from the R1-base plate 310, creating a U-shaped channel between them. The R1-base plate 310 and each of the R1-flanges 312 may extend longitudinally (along y-axis) to have a length substantially the same as that of the R-lateral panel 302. Each of the R1-flanges 312 may have a width (along x-axis) that may be relatively less than widths of the R-top panel 304 and the R-bottom panel 306. For example, a width of the R1-top flange 312-1 may be approximately half of the horizontal width of the R-top panel 304. Similarly, a width of the R1-bottom flange 312-2 may be approximately half of the horizontal width of the R-bottom panel 306.

Further, the R1-base plate 310 may have a vertical height (or width along z-axis) relatively greater than that of the R-lateral panel 302 in order to receive the R-first part 300 within the U-shaped channel of the first R-cover attachment 308. The R1-base plate 310 may include a hardware port such as the physical electrical port 314 to connect with any suitable electrical connectors (not shown) such as those mentioned above. The electrical port 314 may align with and pass through the first hole RH1 when the R1-base plate 310 of the first R-cover attachment 308 may be mounted in contact with the R-lateral panel 302. Upon being mounted, the R1-flanges 312 may extend over the R-top panel 304 and the R-bottom panel 306, and the electrical port 314 may be disposed in the first interior volume of the first EMC housing 210-1. Each of the R1-flanges 312 may extend to cover portions, e.g., approximately half widths (along x-axis), of the corresponding R-top panel 304 and R-bottom panel 306. In the illustrated embodiment, the R1-top flange 312-1 further includes a first R-cut-out 326-1 configured to align with the second hole RH2 in the R-top panel 304. The first R-cut-out 326-1 may assist in preventing the R1-top flange from blocking or covering the second hole RH2 in the R-top panel 304. The first R-cover attachment 308 may implement a double-sheet design by attaching to inner portions (including the R-lateral panel 302 and portions of the R-top panel 304 and the R-bottom panel 306) of the R-first part 300. This double-sheet design may assist in preventing leakage or release of unintended electromagnetic emissions (e.g., unintended radiated emissions) through the R-outermost sides of the first EMC housing 210-1, where the R-outermost sides may include the first R-cover attachment 308 forming the first lateral side of the first EMC housing 210-1.

Similar to the first R-cover attachment 308, a second R-cover attachment 320 may be attached to the R-first part 300. The second R-cover attachment 320 may be made up of a single-sheet configured to assist in covering a second lateral side (e.g., left lateral side) of the first EMC housing 210-1; however, some examples may include the second R-cover attachment 320 also having a double-sheet design as discussed above. In one embodiment, as illustrated in FIG. 8, the second R-cover attachment 320 may be configured as a U-shaped bracket including a U-shaped channel defined by a R2-base plate 322, a R2-top flange 324-1 and a R2-bottom flange 324-2 (collectively referred to as R2-flanges 324), both extending outward in the same direction at approximately 90 degrees from the R2-base plate 322. In the second R-cover attachment 320, the R2-base plate 322 and each of the R2-flanges 324 may extend longitudinally (along y-axis) to have a length approximately the same as that of the R-top panel 304 and the R-bottom panel 306. Each of the R2-flanges 324 may have a width (along x-axis) that may be relatively less than widths (along x-axis) of the R-top panel 304 and the R-bottom panel 306. For example, a width of the R2-top flange 324-1 may be approximately half of the horizontal width of the R-top panel 304. Similarly, a width of the R2-bottom flange 324-2 may be approximately half of the horizontal width of the R-bottom panel 306.

Further, the R2-base plate 322 may have a vertical height (or width along z-axis) relatively greater than the horizontal width (along x-axis) of the R-top panel 304 and the R-bottom panel 306. The R2-base plate 322 may also include a third hole RH3 (shown in FIG. 8 and FIG. 10) and a fourth hole RH4 (shown in FIG. 10) to allow electrical connectors to pass therethrough. In some examples, the third hole RH3 may be disposed opposite to the first hole RH1 in the same horizontal plane or axis. As illustrated in FIG. 9, the second R-cover attachment 320 may be mounted on to the R-first part 300. The second R-cover attachment 320 may receive the R-first part 300 in the U-shaped channel with the R2-top flange 324-1 mounted onto the R-top panel 304 and the R2-bottom flange 324-2 mounted on to the R-bottom panel 306. Upon being mounted, the R2-top flange 324-1 may longitudinally align with and meet the R1-top flange 312-1 of the first R-cover attachment 308 to create a first seam S1 (or joint line) on the R-top panel 304. The R2-top flange 324-1 may also include a second R-cut-out 326-2 configured to align with the second hole RH2 in the R-top panel 304. The second R-cut-out 326-2 may assist in preventing the R2-top flange 324-1 from blocking or covering the second hole RH2 in the R-top panel 304. Accordingly, the R1-top flange 312-1 and R2-top flange 324-1 may together cover the R-top panel 304 without blocking the second hole RH2. Similarly, the R2-bottom flange 324-2 may longitudinally align with and meet the R1-bottom flange 312-2 of the first R-cover attachment 308 to create a second seam (or joint line) on the R-bottom panel 306. Accordingly, the R1-bottom flange 312-2 and R2-bottom flange 324-2 may together cover the R-bottom panel 306. Thus, the second R-cover attachment 320 and the first R-cover attachment 308 may together encase the R-first part 300 between them to create a R-second part 340 without blocking or covering the second hole RH2 in the R-top panel 304. Moreover, since each of the first seam S1 and the second seam (hereinafter collectively referred to as R-seams) is formed over a solid electrically conductive barrier created by the R-top panel 304 and the R-bottom panel 306, respectively, the R-seams do not cause or allow unintended electromagnetic emissions such as unintended radiated emissions from leaking through them, thereby preventing the creation of slot antennas.

The R-second part 340 may have an open front side and an open rear side (not shown). The front side may be covered by a R-front panel 328-1 (shown in FIG. 10) and the rear side may be covered by a R-rear panel 328-2 (shown in FIG. 11) to form the first EMC housing 210-1. Each of the R-front panel 328-1 and the R-rear panel 328-2 (hereinafter collectively referred to as R-panels) may include a vent section in a top portion; however, some examples may include the vent section disposed in a lower portion of the R-front panel 328-1 and/or the R-rear panel 328-2 depending on the positioning of various functional units within the first interior volume of the first EMC housing 210-1. For example, the R-front panel 328-1 may include a first R-vent section 330-1 and the R-rear panel 328-2 may include a second R-vent section 330-2. Each of the first R-vent section 330-1 and the second R-vent section 330-2 (hereinafter collectively referred to as R-vent sections 330) may provide a consolidated set of multiple hexagonal or square openings (hereinafter referred to as honeycomb vents) to permit airflow for cooling and maintain electromagnetic shielding. Each of the honeycomb vents may have an aperture width (or cell size) ranging from approximately 3 mm to approximately 6 mm or at least less than a half of wavelength of unintended radiated emissions generated by functional units inside the first EMC housing 210-1 to prevent these emissions to release into the external environment.

Unlike the traditional component box such as box B1 having large spread of variable-size and scattered openings O that act as slot antennas, the consolidated design of the R-vent sections 330 along with calibrated-small-size honeycomb vents may assist in preventing unintended radiation leakage while supporting airflow for heat dissipation from the first interior volume of the first EMC housing 210-1. Further, each of the R-vent sections 330 may include a fan (not shown) mounted therewith for cooling the first interior volume of the first EMC housing 210-1. For example, a fan may be mounted on each of the R-panels, e.g., over the respective R-vent sections 330. The fan may be mounted in the first interior volume of first EMC housing 210-1; however, some examples may include the mounted on the R-panels outside the first EMC housing 210-1. Such fan may blow cool air into or suck hot air out of the first EMC housing 210-1 for heat dissipation.

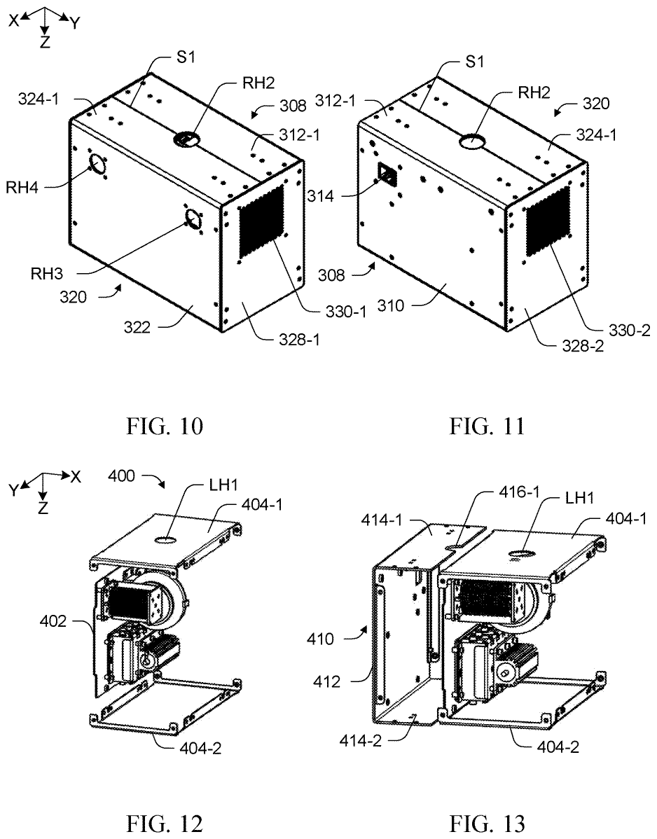

The second EMC housing 210-2 may be constructed similar to the first EMC housing 210-1. As illustrated in FIG. 12, the second EMC housing 210-2 may include a L-lateral panel 402, a L-top panel 404-1, and a L-bottom panel 404-2. The L-lateral panel 402 may be oriented towards a first lateral side (e.g., left lateral side) of the second EMC housing 210-2. The L-lateral panel 402 may have a length (along y-axis) approximately the same as lengths (along y-axis) of both the L-top panel 404-1 and the L-bottom panel 404-2. The L-lateral panel 402 may have a vertical height (or width along z-axis) greater than a horizontal width (along x-axis) of both the L-top panel 404-1 and the L-bottom panel 404-2. The L-lateral panel 402 may provide a base for mounting a group of one or more intended functional units. The L-lateral panel 402 may be arranged parallel to the vertical axis of the chassis 120 or the robot 102. The L-lateral panel 402 may be mounted perpendicularly to edges (along y-axis) of both the L-top panel 404-1 and the L-bottom panel 404-2 to create a L-first part 400 of the second EMC housing 210-2. The vertical arrangement of the functional units mounted to the L-lateral panel 402 may provide benefits similar to those discussed above with respect to the vertical mounting of functional units on the R-lateral panel 302. In the illustrated embodiment, the L-lateral panel 402 may create a separation between the L-top panel 404-1 and the L-bottom panel 404-2 to assist in creating a second interior volume for the second EMC housing 210-2 for accommodating the intended functional units. The second EMC housing 210-2 may define the second interior volume and various openings to the second interior volume. For example, the L-top panel 404-1 may include a first hole LH1 to allow any suitable electrical connectors to pass therethrough, discussed below in greater detail.

In one embodiment, the L-first part 400 may be mounted with a first L-cover attachment 410. As illustrated in FIG. 13, the first L-cover attachment 410 may include a L1-base plate 412, a L1-top flange 414-1, and a L1-bottom flange 414-2 (collectively referred to as L1-flanges 414). The first L-cover attachment 410 may be configured as a U-shaped bracket having both the L1-flanges 414 extending outward in the same direction at approximately 90 degrees from the L1-base plate 412, creating a U-shaped channel between them. The L1-base plate 412 and each of the L1-flanges 414 may extend longitudinally (along y-axis) to have a length substantially the same as that of the L-lateral panel 402. Each of the L1-flanges 414 may have a width (along x-axis) that may be relatively less than widths of the L-top panel 404-1 and the L-bottom panel 404-2. For example, a width of the L1-top flange 414-1 may be approximately half of the horizontal width (along x axis) of the L-top panel 404-1. Similarly, a width of the L1-bottom flange 414-2 may be approximately half of the horizontal width (along x axis) of the L-bottom panel 404-2. Further, the L1-base plate 412 may have a vertical height (or width along z-axis) relatively greater than that of the L-lateral panel 402 in order to receive the L-first part 400 within the U-shaped channel of the first L-cover attachment 410.

Upon mounting the L1-base plate 412 of the first L-cover attachment 410 in contact with the L-lateral panel 402, the L1-flanges 414 may extend over the L-top panel 404-1 and the L-bottom panel 404-2. Each of the L1-flanges 414 may extend to cover portions, e.g., approximately half widths, of the corresponding L-top panel 404-1 and L-bottom panel 404-2. The L1-top flange 414-1 may also include a first L-cut-out 416-1 configured to align with the first hole LH1 in the L-top panel 404-1. The first L-cut-out 416-1 may assist in preventing the L-top flange from blocking or covering the first hole LH1 in the L-top panel 404-1. The first L-cover attachment 410 may implement a double-sheet design by attaching to inner portions (including the L-lateral panel 402 and portions of the L-top panel 404-1 and the L-bottom panel 404-2) of the L-first part 400. This double-sheet design may assist in preventing leakage or release of unintended electromagnetic emissions such as unintended radiated emissions through the L-outermost sides of the second EMC housing 210-2, where the L-outermost sides may include the first L-cover attachment 410 forming the first lateral side of the second EMC housing 210-2.

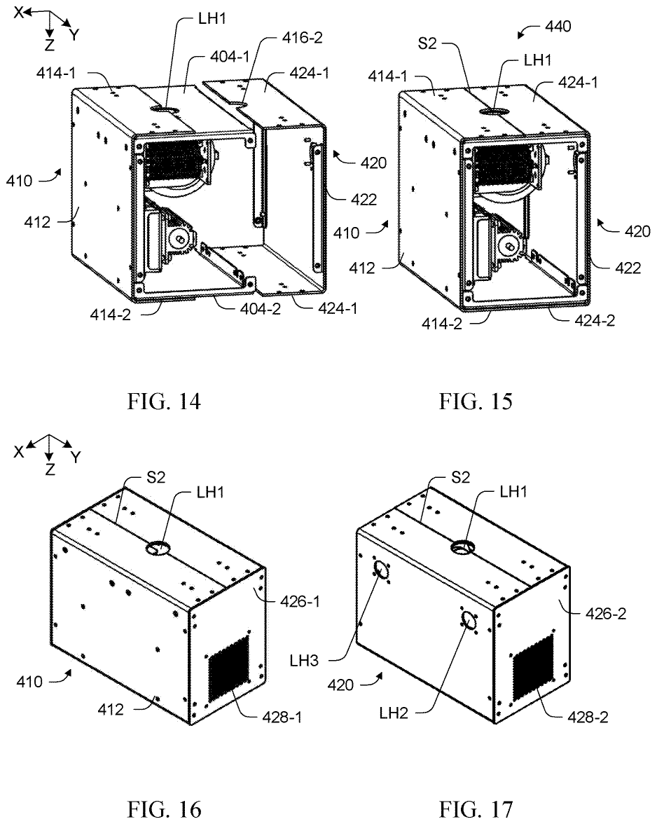

Similar to the first L-cover attachment 410, a second L-cover attachment 420 may be attached to the L-first part 400. The second L-cover attachment 420 may be made up of a single-sheet configured to assist in covering a second lateral side of the second EMC housing 210-2; however, some examples may include the second L-cover attachment 420 also having a double-sheet design as discussed above. In one embodiment, as illustrated in FIG. 14, the second L-cover attachment 420 may be configured as a U-shaped bracket including a U-shaped channel defined by a L2-base plate 422, a L2-top flange 424-1 and a L2-bottom flange 424-2 (collectively referred to as L2-flanges 424), both extending outward in the same direction at approximately 90 degrees from the L2-base plate 422. In the second L-cover attachment 420, the L2-base plate 422 and each of the L2-flanges 424 may extend longitudinally (along y-axis) to have a length approximately the same as that of the L-top panel 404-1 and the L-bottom panel 404-2. Each of the L2-flanges 424 may have a width (along x-axis) that may be relatively less than widths (along x-axis) of the L-top panel 404-1 and the L-bottom panel 404-2. For example, a width of the L2-top flange 424-1 may be approximately half of the horizontal width of the L-top panel 404-1. Similarly, a width of the L2-bottom flange 424-2 may be approximately half of the horizontal width of the L-bottom panel 404-2. Further, the L2-base plate 422 may have a vertical height (or width along z-axis) relatively greater than the horizontal width (along x-axis) of the L-top panel 404-1 and the L-bottom panel 404-2. The L2-base plate 422 may also include a second hole LH2 and a third hole LH3 (shown in FIG. 17) to allow any suitable electrical connectors to pass therethrough.

As illustrated in FIG. 15, the second L-cover attachment 420 may be mounted on to the L-first part 400. The second L-cover attachment 420 may receive the L-first part 400 in the U-channel with the L2-top flange 424-1 mounted onto the L-top panel 404-1 and the L2-bottom flange 424-2 mounted on to the L-bottom panel 404-2. Upon being mounted, the L2-top flange 424-1 may longitudinally align with and meet the L1-top flange 414-1 of the first L-cover attachment 410 to create a first seam S2 (or joint line) on the L-top panel 404-1. The L2-top flange 424-1 may also include a second L-cut-out 416-2 configured to align with the first hole LH1 in the L-top panel 404-1. The second L-cut-out 416-2 may assist in preventing the L2-top flange 424-1 from blocking or covering the first hole LH1 in the L-top panel 404-1. Accordingly, the L1-top flange 414-1 and L2-top flange 424-1 may together cover the L-top panel 404-1 without blocking the first hole LH1. Similarly, the L2-bottom flange 424-2 may longitudinally align with and meet the L1-bottom flange 414-2 of the first L-cover attachment 410 to create a second seam (or joint line) on the L-bottom panel 404-2. Accordingly, the L1-bottom flange 414-2 and L2-bottom flange 424-2 may together cover the L-bottom panel 404-2. Thus, the second L-cover attachment 420 and the first L-cover attachment 410 may together encase the L-first part 400 between them to create a L-second part 440 without blocking or covering the first hole LH1 in the L-top panel 404-1. Moreover, since each of the first seam S2 and the second seam (hereinafter collectively referred to as L-seams) is formed over a solid electrically conductive barrier created by the L-top panel 404-1 and the L-bottom panel 404-2, respectively, the L-seams do not cause or allow unintended electromagnetic emissions such as unintended radiated emissions from leaking through them, thereby preventing the creation of slot antennas.

The L-second part 440 may have an open front side and an open rear side (not shown). The front side may be covered by a L-front panel 426-1 (shown in FIG. 16) and the rear side may be covered by a L-rear panel 426-2 (shown in FIG. 17) to form the second EMC housing 210-2. Each of the L-front panel 426-1 and the L-rear panel 426-2 (hereinafter collectively referred to as L-panels 426) may include a vent section in a lower portion; however, some examples may include the vent section disposed in an upper portion of the L-front panel 426-1 and/or the L-rear panel 426-2 depending on the positioning of various functional units within the second interior volume of the second EMC housing 210-2. For example, the L-front panel 426-1 may include a first L-vent section 428-1 and the L-rear panel 426-2 may include a second L-vent section 428-2. Each of the first L-vent section 428-1 and the second L-vent section 428-2 (hereinafter collectively referred to as L-vent sections 428) may provide a consolidated set of multiple hexagonal or square openings (hereinafter referred to as honeycomb vents) to permit airflow for cooling and maintain electromagnetic shielding. Each of the honeycomb vents may have an aperture width (or cell size) ranging from approximately 3 mm to approximately 6 mm or at least less than a half of wavelength of unintended radiated emissions to prevent their leakage. The L-vent sections 428 may provide benefits similar to those described above for R-vent sections 330. Further, each of the L-vent sections 428 may include a fan (not shown) mounted therewith for cooling the second interior volume of the second EMC housing 210-2. For example, a fan may be mounted on each of the L-panels 426, e.g., over the respective L-vent sections 428. The fan may be mounted in the second interior volume of second EMC housing 210-2; however, some examples may include the mounted on the L-panels 426 outside the second EMC housing 210-2. The fan may blow cool air into or suck hot air out of the second EMC housing 210-2. The second EMC housing 210-2 may be assembled with the first EMC housing 210-1.

Each of the panels, attachments, and brackets including vent sections as described in the present application may be connected to each other using any suitable connection mechanisms known in the art, related art, or developed later and made up of or include electrically conductive materials such as those mentioned above. One example of these connection mechanisms may include, but are not limited to, bolts, either alone or in combination with suitable EMI gaskets, conductive pastes, or other materials that may be electrically conductive in nature and/or assist in electromagnetic shielding. In some examples, the bolts may assist in preventing any unintended openings at points of connection.

In one embodiment, the first EMC housing 210-1 and the second EMC housing 210-2 (collectively referred to as lower housings) may be placed adjacent to each other and joined using any suitable connection mechanisms know in the art including those mentioned above. For example, the first EMC housing 210-1 may be attached laterally (along longitudinal axis) to the second EMC housing 210-2 using one or more metal plates (not shown) extending across both the first EMC housing 210-1 and the second EMC housing 210-2. The metal plates may be disposed under the L-bottom panel 404-2 and the R-bottom panel 306.

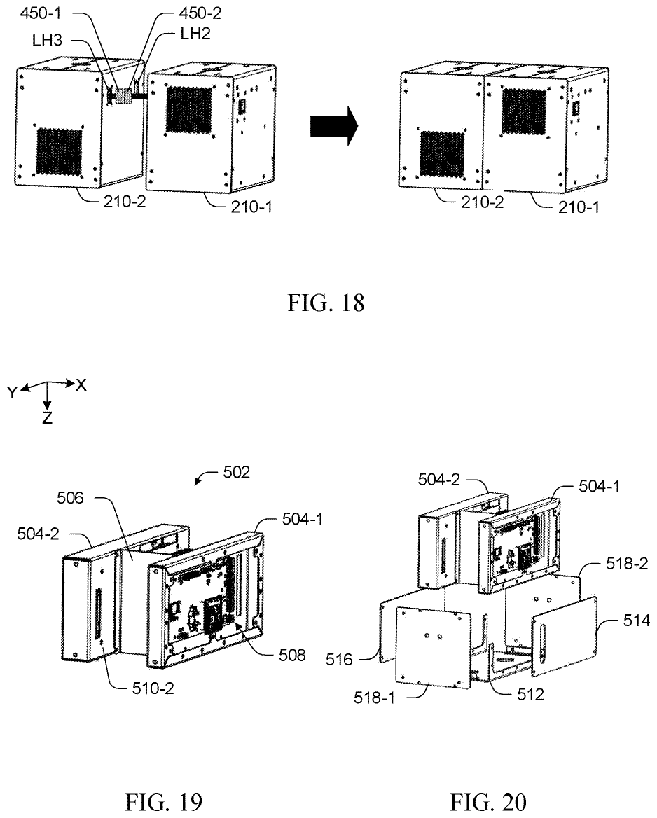

As illustrated in FIG. 18, the first EMC housing 210-1 may be disposed in contact with the second EMC housing 210-2 without any gaps between them. In the illustrated embodiment, the lower housings may be attached in a manner that the second R-cover attachment 320 may be placed in contact with the second L-cover attachment 420. Since both the second R-cover attachment 320 and the second L-cover attachment 420 (collectively referred to as inner cover attachments) have a single-sheet design, joining the inner cover attachments together creates a double-wall structure having double thickness to further assist in reducing unintended electromagnetic emissions and coupling across the lower housings. When attached together, the inner cover attachments may have the holes in the respective lower housings align with each other. For example, the holes RH3 and RH4 (in the second R-cover attachment 320 of the first EMC housing 210-1) may axially align (e.g., along the horizontal axis) with the holes LH3 and LH2 (in the second L-cover attachment 420 of the second EMC housing 210-2), respectively, when the lower housings may be attached laterally. These aligned holes may assist in passing any suitable electrical connectors internally between the lower housings for power and/or control signals. Such internal passing of electrical connectors maintains them within the first EMC apparatus 202, thereby preventing unintended electromagnetic radiation emissions from these electrical connectors from being released outside the EMC apparatus and the EMC system 110 into the external environment. Further, each of the electrical connectors may be mounted with a ferrite material, such as ferrites 450-1 and 450-2, whenever any electrical connector passes internally from any EMC housing, such as the first EMC housing 210-1, to another EMC housing, such as the second EMC housing 210-2, or vice versa. Such ferrite material may be located in the interior volume of the either of the underlying EMC housings.

The lower housings may distribute, isolate, and enclose a group of functional units between them for driving the load unit 106. In one embodiment, the first EMC housing 210-1 may include a first group of one or more intended functional units, which individually or in combination with each other, being configured to (1) receive a first input voltage signal (e.g., 120V AC), and (2) generate a first output voltage signal (e.g., approximately 340V DC) and a second output voltage (e.g., approximately 240V AC) based on the first input voltage signal. The first input voltage signal may be received from AC mains via the electrical port 314; however, some examples may include the first input voltage signal being received from batteries or the remote device via the electrical port 314. In further examples, the first EMC housing 210-1 may additionally receive a second input voltage signal (e.g., 12V DC) from the third EMC housing 210-3, e.g., to run any fans in the first EMC housing 210-1, via any suitable electrical connectors mounted with ferrite materials. Other examples may include a set of one or more functional units in the first EMC housing 210-1 additionally operating to convert a first input current (e.g., AC) into a first output current (e.g., higher or lower DC) and a second output current (e.g., higher or lower AC). The first input voltage signal, the first output voltage signal, and/or the second output voltage signal may be supplied to other housings of the EMC system 110, e.g. to the second EMC housing 210-2 and the third EMC housing 210-3, or vice versa, via any suitable electrical connectors such as those mentioned above.

In one embodiment, the second EMC housing 210-2 may include a second group of one or more functional units, which individually or in combination with each other or the first group, being configured to (1) receive the first output voltage signal (e.g., approximately 340V DC) from the first EMC housing 210-1 via any suitable electrical connectors passing through either a first set of holes LH2, RH4 and a second set of holes LH3, RH3; (2) generate a third output voltage (e.g., 3000V chopped DC or 3000V AC) based on the first output voltage signal received from the first EMC housing 210-1; (3) receive the second input voltage signal (e.g., 12V DC) and a third input voltage signal (e.g., 1000V AC) from the third EMC housing 210-3; and (4) generate a fourth output voltage (e.g., 15000V DC or 15000V AC) based on the third input voltage signal received from the third EMC housing 210-3. Both the second input voltage signal and third input voltage signal may be received via any suitable electrical connectors, which may (i) extend from the third EMC housing 210-3 into the first EMC housing 210-1 and (ii) then from the first EMC housing 210-1 pass into the second EMC housing 210-2 through the first set of holes LH2, RH4, and/or the second set of holes LH3, RH3 in the lower housings. However, some examples may include the second EMC housing 210-2 receiving the second input voltage signal or the third input voltage signal from the first group in the first EMC housing 210-1. Other examples may include the second EMC housing 210-2 further receiving the first input voltage signal from the first EMC housing 210-1. The second input voltage signal may be used for driving the heat management units (e.g., fans) in the first EMC housing 210-1 and/or the second EMC housing 210-2. Alongside, the third output voltage and the fourth output voltage may be used for driving the primary load. Each of the first EMC housing 210-1 and the second EMC housing 210-2 may be further placed in contact with the third EMC housing 210-3.

In the illustrated embodiment of FIG. 19, the third EMC housing 210-3 may include an H-shaped modular frame 502 comprising a first casing 504-1 and a second casing 504-2 (hereinafter collectively referred to as casings 504). Each of the casings 504 may be arranged longitudinally parallel to each other. The casings 504 may be connected by a connector plate 506 extending transversely relative to the longitudinal axes of the casings 504. The connector plate 506 may have a length defining a fixed spacing and distance between the casings 504. The connector plate 506, together with the casings 504, forms the H-shape of the modular frame 502. Each of the casings 504 may have a hollow, box-like configuration including an interior cavity defined by side walls with an open front face. For example, as illustrated, the first casing 504-1 may have a first interior cavity 508 and an open front face providing access to the first interior cavity 508. Similarly, the second casing 504-2 may have a second interior cavity (not shown) that may be accessed from the corresponding open front face. Each of the first interior cavity 508 and the second interior cavity (hereinafter collectively referred to as interior cavities) may function as a receptacle for mounting one or more intended functional units thereto. For example, the first interior cavity 508 may be configured to mount a third group of one or more functional units, which may include electrical switching components. Similarly, the second interior cavity may be configured to mount a fourth group of one or more functional units, which may include electrical switching components. The interior cavities may extend along at least a substantial length of the corresponding casings 504.

Further, each of the casings 504 may have their respective front faces oriented away from each other. For example, the first casing 504-1 may have its front face oriented away from the second casing 504-2. Opposite to the front face, the first casing 504-1 may include a first rear plate 510-1 oriented towards the other second casing 504-2. Similar to the first rear plate 510-1, the second casing 504-2 may have a second rear plate 510-2 opposite its own open front face (not shown). The second rear plate 510-2 may be oriented towards the first casing 504-1. Each of the first rear plate 510-1 and the second rear plate 510-2s (hereinafter collectively referred to as rear plates 510) may have an inner surface and an outer surface opposite thereto. The inner surface may be disposed in the corresponding interior cavity and configured to mount an intended group of one or more functional units. The outer surface may be configured to attach the connector plate 506. As such, opposing ends of the connector plate 506 may be attached to the outer surfaces of the rear plates 510 of the respective casings 504 to maintain the modular frame 502 in fixed, spaced, parallel arrangement. The length of each of the casings 504 may be greater than the length (or a width) of the connector plate 506.

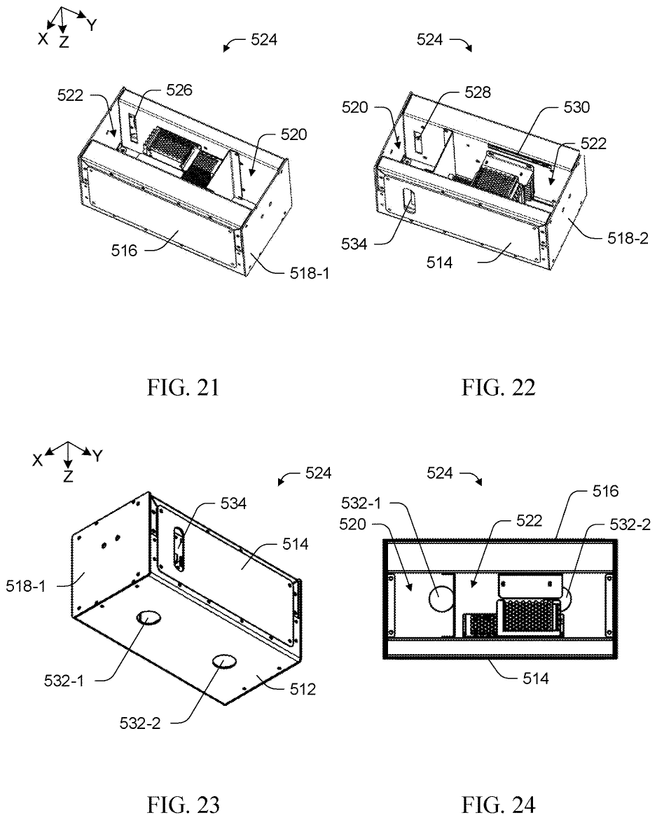

As illustrated in FIG. 20, the modular frame 502 may be mounted on a base bracket 512 and attached with additional plates. For example, the first casing 504-1 may have its open front face attached to a first outer plate 514 for covering the first interior cavity 508. Similarly, the second casing 504-2 may have a second outer plate 516 attached to the corresponding front face for covering the second interior cavity. Further, the H-shaped modular frame 502 may be attached with a first lateral plate 518-1 and a second lateral plate 518-2 (hereinafter collectively referred to as lateral plates) to define associated compartments. For example, as illustrated in FIG. 21, a first lateral plate 518-1 may be attached to a first open end of the H-shaped modular frame 502. The first lateral plate 518-1 may extend between the casings 504 and secured to a first set of lateral edges of the casings 504 near the first open end. The first lateral plate 518-1 along with the connector plate 506 and adjacent portions of rear plates 510 of the casings 504 may create a first compartment 520. Similarly, a second lateral plate 518-2 may be attached to a second open end of the H-shaped modular frame 502. The second lateral plate 518-2 may extend between the casings 504 and secured to a second set of lateral edges of the casings 504 near the second open end. The second lateral plate 518-2 along with the connector plate 506 and adjacent portions of rear plates 510 of the casings 504 may create a second compartment 522. The H-shaped modular frame 502 mounted with the base bracket 512, the first outer plate 514, the second outer plate 516, the first lateral plate 518-1, and the second lateral plate 518-2 may form an open-housing 524.

In one embodiment, the first rear plate 510-1 (of the first casing 504-1) may include a first opening 526 (shown in FIG. 21) providing a passage from the first interior cavity 508 into the second compartment 522. Similarly, the second rear plate 510-2 (of the second casing 504-2) may include a second opening 528 and a third opening 530 (shown in FIG. 22). The second opening 528 may provide a passage from the second interior cavity into the first compartment 520. The third opening 530 may provide a passage from the second interior cavity into the second compartment 522. In one embodiment, the first compartment 520 may be kept devoid of any electrical switching components that may generate unintended electromagnetic emissions (e.g., unintended radiated emissions). For example, the first compartment 520 may exclude any type of functional units (e.g., voltage or current switching components) from being mounted therein. In another embodiment, the first compartment 520 may be kept devoid of any and all functional units and/or electrical, electronic, or electromechanical components. Further, the first compartment 520 may be configured to allow any suitable electrical connectors to pass therethrough. For example, as illustrated in FIG. 23, the base bracket 512 may include a first base hole 532-1 providing a passage into the first compartment 520, and a second base hole 532-2 providing a passage into the second compartment 522. Further, the second compartment 522 may be configured to include a fifth group of one or more intended functional units, which may be mounted to a portion of the second rear plate 510-2 of the second casing 504-2; however, some examples may include the one or more intended functional units being alternatively, or additionally, mounted to a portion of the first rear plate 510-1 in the second compartment 522. The fifth group of one or more intended functional units may include electrical switching components (e.g., voltage or current switching components).

Further, as illustrated in FIG. 23, the first casing 504-1 may further include the first outer plate 514 having a front slot 534 to assist in reducing obstruction to intentional radiated emissions, such as wireless RF signals, for remote communication. As discussed above, a cell size of the front slot 534 should be less than a half of wavelength of radiated emissions from the underlying functional units to prevent their leakage or release outside the first casing 504-1 or the third EMC housing 210-3. However, having such cell size may also obstruct intentional wireless RF signals to and from a functional unit (e.g., wireless communication unit incl. an antenna) of the third group in the first interior cavity 508 to limit an intended range of the signal strength of the intentional wireless RF signals required for remote communication. Therefore, the cell size of the of the front slot 534 may be dependent on a trade-off between restricting leakage or release of unintentional radiated emissions and allowing intentional wireless RF signals to pass external to the first casing 504-1 and the third EMC housing 210-3 without unwanted hinderance/attenuation. In one embodiment, for a 2.4 GHz Wi-Fi® signal generated by the functional unit in the third group, the front slot 534 measuring 6 mm or less may curb unintended radiated emissions but may also obstruct a range of reliable Wi-Fi® signals for remote communication. It is observed that the front slot 534 having a longest/maximum linear dimension size of 6 mm (e.g., 6 mm×6 mm, 6 mm×5 mm, 6 mm×4 mm, 6 mm×3 mm, 6 mm×2 mm, or 6 mm×1 mm) may allow an intended radiated signal, such as the Wi-Fi® signal, with a signal strength ranging from approximately-75 dBm to approximately-65 dBm to propagate over approximately 3 feet (or 0.91 meters) from the first casing 504-1. In this scenario, alongside such low, variable signal strength being extremely unreliable during robot operation, the 3-foot Wi-Fi® range may be impractical for communicating with an intended remote device. As such, a maximum linear dimension of the front slot 534 may be increased, for example, up to 90 mm to transform the single front slot 534 into a rectangular slot having a size up to, e.g., 90 mm by 24 mm, 90 mm×20 mm, 90 mm×15 mm, 90 mm×10 mm, 90 mm×5 mm, and so on, to increase the signal strength of intentional radio such Wi-Fi® signals up to −58 dBM that may remain effective to a range up to 14 meters.

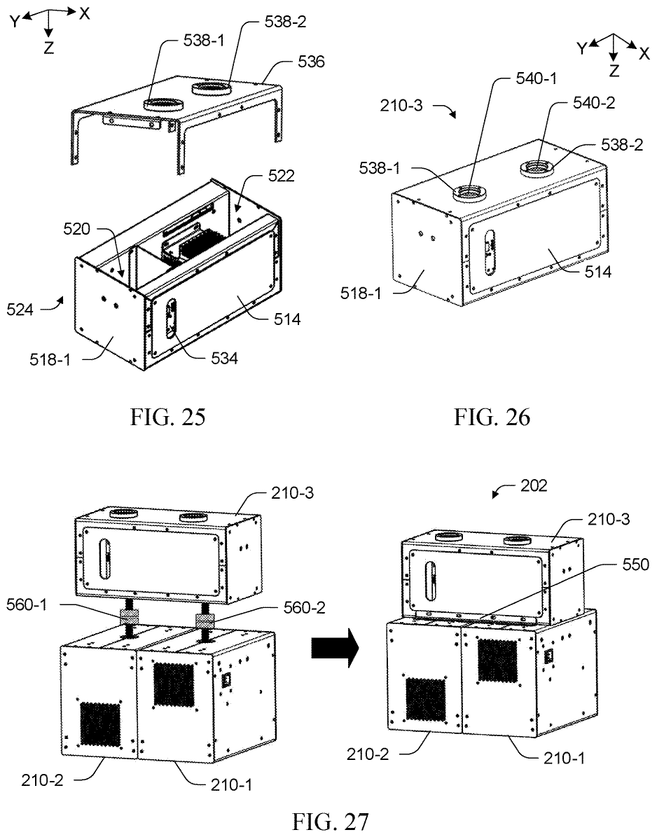

Further, as illustrated in FIG. 24, the first compartment 520 may communicate with the first base hole 532-1 located in the base bracket 512. Similarly, the second compartment 522 may communicate with the second base hole 532-2 located in the base bracket 512. Each of the first base hole 532-1 and the second base hole 532-2 (hereinafter collectively referred to as base holes 532) may align with the corresponding holes in a top bracket 536. As illustrated in FIG. 25, the open-housing 524 may be configured to receive the top bracket 536. In one embodiment, the top bracket 536 may have a length and a width commensurate with those of the modular frame 502 and/or the open-housing 524. As illustrated in FIG. 26, the top bracket 536 mounted to the open-housing 524 may form the third EMC housing 210-3. The top bracket 536 may include a first top clamp 538-1 and a second top clamp 538-2 (hereinafter collectively referred to as top clamps 538). The top clamps 538 may be mounted on an outer surface, such as a top surface, of the top bracket 536. The top clamps 538 may be configured to assist in physically connecting the third EMC housing 210-3 (and the first EMC apparatus 202) with the second EMC apparatus 204.

Further, the third EMC housing 210-3 may define a third interior volume and various openings to the third interior volume. For instance, each of the top clamps 538 may include holes. For example, the first top clamp 538-1 may include a first top hole 540-1 and the second top clamp 538-2 may include a second top hole 540-2. Each of the first top hole 540-1 and the second top hole 540-2 (hereinafter collectively referred to as top holes 540) may assist in passing any suitable electrical connectors from the first EMC apparatus 202 to the second EMC apparatus 204. The first top hole 540-1 may be disposed in communication with the first compartment 520. The first top hole 540-1 may be axially aligned with the first base hole 532-1 in the base bracket 512. Similarly, the second top hole 540-2 may be disposed in communication with the second compartment 522. The second top hole 540-2 may be axially aligned with the second base hole 532-2 in the base bracket 512. The top holes 540 may assist the third EMC housing 210-3 (and/or other EMC housings 210 in the first EMC apparatus 202) to communicate with the load unit 106.

In one embodiment, as illustrated in FIG. 27, the third EMC housing 210-3 may be placed adjacent to the first EMC housing 210-1 and the second EMC housing 210-2 and joined together using any suitable connection mechanisms know in the art including those mentioned above. For example, the third EMC housing 210-3 may be mounted on top of both the lower housings; however, some examples may include the third EMC housing 210-3 mounted laterally in contact with at least one of the first EMC housing 210-1 and the second EMC housing 210-2. As illustrated, the third EMC housing 210-3 may be mounted across the longitudinal axes of both the first EMC housing 210-1 and the second EMC housing 210-2 using angular metal brackets such as a metal bracket. When mounted, a longitudinal axis of the third EMC housing 210-3 may be perpendicular to the longitudinal axes of the each of the lower housings. The third EMC housing 210-3 may have the base bracket 512 disposed in direct contact with each of the R-top panel 304 (of the first EMC housing 210-1) and the L-top panel 404-1 (of the second EMC housing 210-2) with no gaps therebetween. Upon being mounted, the third EMC housing 210-3 may have the second top hole 540-2 and/or the second base hole 532-2 axially aligned (e.g., vertically) with the hole RH2 of the first EMC housing 210-1, and the first base hole 532-1 and the first top hole 540-1 axially aligned (e.g., vertically) with the hole LH1 of the second EMC housing 210-2. These aligned holes may assist in passing any suitable electrical connectors internally between the third EMC housing 210-3 and the lower housings for power and/or control signals. Such internal passing of electrical connectors within the first EMC apparatus 202 may prevent unintended electromagnetic radiation emissions from these electrical connectors from being released outside the first EMC apparatus 202 and the EMC system 110 into the external environment. Further, each of the electrical connectors may be mounted with a ferrite material, such as ferrites 560-1 and 560-2 (collectively ferrites 560), whenever any electrical connector passes internally from any EMC housing to another EMC housing, for example, from the first EMC housing 210-1 to the third EMC housing 210-3, vice versa, or alternatively, from the second EMC housing 210-2 to the third EMC housing 210-3, or vice versa. Such ferrite material, such as ferrites 560) may be located in the interior volume of the either of the underlying EMC housings of the EMC system 110.

The third EMC housing 210-3 may also distribute, isolate, and enclose various intended groups of functional units for driving the load unit 106. For instance, the second compartment 522 may include the fifth group of one or more functional units, either individually or in combination with other functional groups, configured to (1) receive the first input voltage signal (e.g., 120V AC) and the second output voltage signal (e.g., approximately 240V AC) from the first EMC housing 210-1 via any suitable electrical connectors passing through the second base hole 532-2 in the base bracket 512; (2) generate the second input voltage signal (e.g., 12V DC) based on the first input voltage signal (e.g., 120V AC); and (3) generate a fourth input voltage signal (e.g., 3V DC, 3.3V DC, or 3.6V DC, etc.) based on the first input voltage signal (e.g., 120V AC).

Similarly, the first interior cavity 508 may have the third group of one or more functional units, either individually or in combination with other functional groups, configured to (1) generate intentional wireless RF signals, such as Wi-Fi® signals based on the fourth input voltage signal for wireless communication with a remote device such as those mentioned above; and (2) generate a fifth input voltage signal (e.g., 3V DC, 3.3V DC, or 3.6V DC, etc.) based on the first input voltage signal (e.g., 120V AC) to trigger various functional units in different groups in the EMC system 110. Further, the second interior cavity may have the fourth group of one or more functional units, either individually or in combination with other functional groups, configured to (1) sense whether the third output voltage (e.g., 3000V chopped DC or 3000V AC) is generated and maintained in the second EMC housing 210-2; and (2) generate the third input voltage signal (e.g., 1000V AC) based on the second output voltage signal. The groups of functional units in the third EMC housing 210-3, along with other groups of functional units in the first EMC housing 210-1 and the second EMC housing 210-2, may drive the load unit 106.

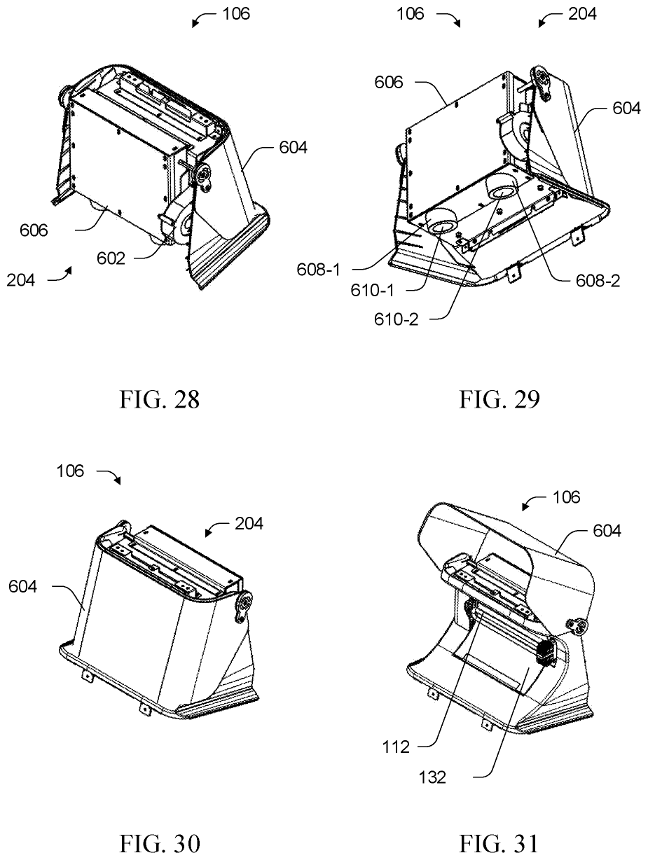

In one embodiment, as illustrated in FIG. 28, the load unit 106 may include the germicidal assembly 130, the second EMC apparatus 204, a blower 602, and a visor assembly including a rotatable visor 604. The germicidal assembly 130 may include the reflector 132 and the germicidal source 112 such as the UV lamp, as discussed above. The germicidal source 112 may be coverable by the rotatable visor 604. The blower 602 and the rotation of the visor 604 may be driven by a group of one or more functional units in the second EMC apparatus 204 operably connected to the first EMC apparatus 202. As illustrated in FIG. 29, the second EMC apparatus 204 may include a load EMC housing 606 constructed to operate as a Faraday enclosure. The load EMC housing 606 may be made up of any suitable electrically conductive materials such as those mentioned above. The load EMC housing 606 (and the second EMC apparatus 204) have a footprint or a geometry relatively smaller than the EMC housings 210 (and hence, the first EMC apparatus 202); however, some examples may include the second EMC apparatus 204 having a geometry relatively greater that that of the first EMC apparatus 202. The smaller footprint and/or geometry of the second EMC apparatus 204 may assist in (1) accommodating the load EMC housing 606 with load unit 106 and/or in the first section 104-1 of the robot 102 while maintaining a stable center of gravity of the robot; and (2) providing an electromagnetically shielded pathway for the first EMC apparatus 202 to drive the primary load, such as the germicidal source 112, while maintaining unintended electromagnetic emissions from the pathway below the permissible limits in the external environment.

In one embodiment, the load EMC housing 606 may be constructed as a closed housing with one or more types of electrical ports. The load EMC housing 606 may have the electrical ports on its outer surface. In one example, the one or more electrical ports may be configured as electrical terminals (not shown) extending outward from an interior volume of the load EMC housing 606. The electrical terminals may assist in establishing a direct contact with the blower 602 and the germicidal source 112 for control and power while avoiding to create radiating antennas. The load EMC housing 606 may have the interior volume configured to mount a group of one or more intended functional units thereto. This intended group (e.g., motor and gear unit, and sensor unit) may be enclosed within the load EMC housing 606 to prevent unintended radiated emissions from being released into the external environment. As illustrated in FIG. 29, the load EMC housing 606 may include a bottom plate including a first base clamp 608-1 and a second base clamp 608-2 (hereinafter collectively referred to as base clamps 608). The base clamps 608 may assist in physically connecting the load unit 106 with the first EMC apparatus 202. Each of the base clamps 608 may include holes extending into the interior volume of the load EMC housing 606. For example, the first base clamp 608-1 may include a first clamp hole 610-1 and the second base clamp 608-2 may include a second clamp hole 610-2. Each of the first clamp hole 610-1 and the second clamp hole 610-2 (hereinafter collectively referred to as clamp holes 610) may assist in connecting any suitable electrical connectors from the first EMC apparatus 202 to the intended group of functional units in the load EMC housing 606 for power and control. By virtue of the load EMC housing 606 being made of electrically conductive materials, the load EMC housing 606 may get electrically grounded to curb the unintended conducted emissions by functional units therein when the load EMC housing 606 may be physically connected to the electrically-conductive first EMC apparatus 202.

Further, the visor 604 may be configured to transition between a closed position and an open position. In the closed position, as illustrated in FIG. 30, the visor 604 may rotate to completely cover the germicidal assembly 130. The visor 604, in the closed position, may assist in protecting the germicidal source 112 and the reflector 132 from dust and accidental damage. As illustrated in FIG. 31, the visor 604 may be rotated by a controller (e.g., main controller in the first casing 504-1 of the third EMC housing 210-3) of the robot 102 to move from the closed position to the open position during robot operation. The controller may also control various other functions of the robot 102. Further, in the open position, the visor 604 may expose the germicidal assembly 130 in the load unit 106 to release the germicide, such as UV light, towards an intended target surface or target direction. The load unit 106, either as a single part or with the load EMC housing 606 and the germicidal assembly 130 as separate parts, may be provided in the retrofittable kit for improving electromagnetic compatibility of an equipment such as the robot 102.

In one embodiment, the load unit 106 may be mounted to the first EMC apparatus 202. As illustrated in FIG. 32, the second EMC apparatus 204 may be configured to connect with a first conduit 702-1 and a second conduit 702-2 (hereinafter collectively referred to as conduits 702). Each of the conduits 702 may have any suitable cross-sectional shape and dimensions commensurate with the top holes 540 (in the third EMC housing 210-3) and the clamp holes 610 (in the load EMC housing 606). For example, each of the conduits 702 may have a first end and a second end. The first end may be dimensionally compatible with the first top hole 540-1 and the first clamp hole 610-1. The second end may be dimensionally compatible with the second top hole 540-2 and the second clamp hole 610-2. As such, the first conduit 702-1 may have one end mounted to the first top clamp 538-1 and the other end mounted to the first base clamp 608-1. The first conduit 702-1 may be mounted so as to seal the first top hole 540-1 and the first clamp hole 610-1, preventing unintended radiated emissions from being released into the external environment.

Similar to the first conduit 702-1, the second conduit 702-2 may have one end mounted to the second top clamp 538-2 and the other end mounted to the second base clamp 608-2. The second conduit 702-2 may be mounted in a manner that seals the second top hole 540-2 and the second clamp hole 610-2, preventing any unintended radiated emissions from being released into the external environment. In some examples, the load unit 106 (and/or the second EMC apparatus 204) may be connected to the first EMC apparatus 202 (and/or the third EMC housing 210-3) using only one of the conduits 702. In such an arrangement, the remaining unused holes of the first EMC apparatus 202 and the second EMC apparatus 204 may be sealed using any suitable electrically conductive materials to prevent the release of unintended electromagnetic emissions into the external environment. The electrical connectors may pass internally through the conduits 702 to connect the functional units in the first EMC apparatus 202 (and the EMC housing 210-3) with the functional units and the primary load coupled to the second apparatus 204 (and the load EMC housing 606) to contain any unintended radiated emissions from being released external to robot 102. These electrical connectors may be further mounted with any suitable ferrite materials such as ferrite 720-1, 720-2 shown in FIG. 32.

To maintain a stable center of gravity of the robot 102 and reliably support the load unit 106 in the first section 104-1 (e.g., upper section 126-1) of the robot 102, a portion of the reflector 132 may be secured to the top platform 124-2 (or the support columns 122) of the chassis 120 in addition to the conduits 702 being mounted to the third EMC housing 210-3 in the first EMC apparatus 202 and the load EMC housing 606 in the second EMC apparatus 204. Both conduits 702 may be provided as part of the retrofittable kit to improve the electromagnetic compatibility of the equipment, such as the robot 102. Accordingly, the first EMC apparatus 202 and the second EMC apparatus 204, along with the conduits 702, may form a closed EMC system 110 that may prevent unintended electromagnetic emissions generated by various functional units within the EMC system 110 from being released outside the EMC system 110 and/or the robot 102.

In one embodiment, the EMC system 110 may further include the third EMC apparatus 800 configured to filter a power signal for providing the first input voltage signal applied to the electrical port 314 at the first EMC housing 210-1. For example, the input power harness 802, which may supply the first input voltage signal, may be attached to the third EMC apparatus 800 before being attached to the electrical port 314. The third EMC apparatus 800 may include one or more functional units operating as a physical noise filter 804 and an input EMC housing 806. The physical noise filter 804, such as an AC filter, may be configured to attenuate unintended conducted emissions (e.g., unwanted high-frequency noise) from the power signal supplying the first input voltage signal (e.g., AC voltage signal) on the input power harness 802. The noise filter 804 may attenuate unintended conducted emissions in the range of 150 kHz to 30 MHz from the power signal while allowing the low-frequency (e.g., 50 Hz or 60 Hz) AC power signal providing the filtered first input voltage signal to pass through the input power harness 802 attached to the electrical port 314 of the first EMC housing 210-1.

In the illustrated embodiment, the physical noise filter 804 may be enclosed within the input EMC housing 806. The input EMC housing 806 may be made up of or include any suitable electrically conductive materials such as those mentioned above. The input EMC housing 806 may be constructed to operate as a Faraday cage. The input EMC housing 806 may be configured to further diminish any unintended radiated emissions generated by a supply power harness 808, which may be attached to an input of the noise filter 804 and connected to the AC supply mains via the power port 108. In some examples, the input EMC housing 806 may also be electrically grounded to further curb the unintended/unwanted conducted emissions from the noise filter 804. In further examples, the supply power harness 808 and the input power harness 802 may be configured as electromagnetically shielded harness and/or enclosed within electrically conductive conduits similar to the conduits 702 to further curb unintended electromagnetic emissions therefrom. Such electromagnetically-shielded supply power harness 808 and the input power harness 802 may further provide the third EMC apparatus 800 in the closed EMC system 110.

Further, the input EMC housing 806 may assist in preventing or minimizing these unintended electromagnetic emissions (such as unintended radiated emissions) from the supply power harness 808 to couple with or latch onto the input power harness 802 attached to an output of the noise filter 804. The third EMC apparatus 800, either as a single part or with the input EMC housing 806 and the noise filter 804 as separate parts, may be provided as part of the retrofittable kit to improve the electromagnetic compatibility of equipment such as the robot 102. The third EMC apparatus 800 may be mounted to the support columns 122 and placed under the first EMC apparatus 202; however, some examples may include the third EMC apparatus 800 being removably secured with any of the first EMC apparatus 202, the second EMC apparatus 204, or any of the underlying EMC housings 210.

During operation, the robot 102 may be operated to drive the primary load, such as the germicidal source 112 (e.g., high-voltage pulsed UV lamp). In one embodiment, the robot 102 may be connected to the AC supply mains via a supply cord (not shown), whose one end may be connected to the power port 108 of the robot 102 and the other end may be inserted into the wall socket or attached to batteries. The power port 108 may be connected to the third EMC apparatus 800 via the supply power harness 808. The third EMC apparatus 800 may include a group of one or more functional units operating as the physical noise filter 804 enclosed within the input EMC housing 806. The supply power harness 808 may be connected to the power port 108 and supply a power signal to the noise filter 804 via the supply power harness 808. The noise filter 804 may attenuate the unintended conducted emissions (e.g., unwanted high-frequency noise) from the power signal to provide the filtered first input voltage signal (e.g., AC voltage signal, or DC voltage signal) to the physical electrical port 314 of the first EMC apparatus 202 via the input power harness 802. The physical electrical port 314 may be attached to the first R-cover attachment 308 that may pass through the first hole RH1 (in the R-lateral panel 302) for being located within the first interior volume of the first EMC housing 210-1. The electrical port 314 may supply the first input voltage signal to one or more of the intended functional units, and/or underlying components, in the first EMC housing 210-1. For example, the first input voltage signal may supply a 120V AC. In the first EMC housing 210-1, a functional unit such as AC-to-DC converter may receive the first input voltage signal (e.g., approximately 120V AC) to generate the first output voltage signal (e.g., approximately 340V DC). Another functional unit such as a voltage transformer may be configured to generate the second output voltage signal (e.g., approximately 240V AC) based on the first input voltage signal. The first output voltage signal may be passed to the one or more functional units in the second EMC housing 210-2 via any suitable electrical connectors passing through, e.g., the holes LH3 and RH3. Similarly, the second output voltage signal may be passed to one or more functional units in the third EMC housing 210-3 via any suitable electrical connectors passing through, e.g., the second base hole 532-2 and RH2. Each of the electrical connectors may be mounted with ferrite material whenever they pass internally from one EMC housing, such as the first EMC housing 210-1, (or one EMC apparatus such as the first EMC apparatus 202) to another EMC housing, such as the second EMC housing 210-2 (or another EMC apparatus such as the second EMC apparatus 204), or vice versa

In the second EMC housing 210-2, a functional unit, such as a toroid transformer, may, directly or indirectly, receive the first output voltage (e.g., approximately 340V DC) to generate the third output voltage (e.g., 3000V chopped DC or 3000V AC), which may be used to power the germicidal source 112 (e.g., high-voltage pulsed UV lamp) in the load unit 106. Another functional unit such as heat management units (e.g., fan) may receive the second input voltage signal (e.g., 12V DC) from the third EMC housing 210-3 via suitable electrical connectors passing internally through any suitable holes within the EMC housings 210. Yet another functional unit such as a trigger controller may receive the third input voltage signal (e.g., 1000V AC) from a lamp controller in the second casing 504-2 of the third EMC housing 210-3, to generate the fourth output voltage (e.g., 15000V DC or 15000V AC), which may be used to trigger the germicidal source 112 at predefined or dynamically defined intervals to output the germicide in a pulsating manner. In one example, the germicidal source 112 such as the UV lamp may emit the UV light having an energy output ranging from approximately 10 J/cm² to approximately 20 J/cm², an energy per pulse ranging from approximately 20 to approximately 150 Joules, and/or at a pulse frequency ranging from 2 Hz to 60 Hz. The second EMC housing 210-2 may further include a sensor unit (e.g., including a temperature sensor) connected to a functional unit (e.g., lamp controller) in the third EMC housing 210-3. The lamp controller (and the third EMC housing 210-3) may stop providing the third input voltage signal to the trigger controller in the second EMC housing 210-2 when a temperature therein increases beyond a set threshold value. From the second EMC housing 210-2, one or more electrical connectors, such as an electrical harness, may extend internally from the second EMC housing 210-2 to the load EMC housing 606 via the first compartment 520 (in the third EMC housing 210-3). The electrical harness may carry high-voltage signals with voltages within a range of 3000V to 15000V at different intervals, as required based on the type of primary load, through the first compartment 520 in the third EMC housing 210-3 to the load EMC housing 606. The first compartment 520 may be completely devoid of any electrical switching components, which may generate unintended electromagnetic emissions (or unwanted noise) that can latch on to the high-tension electrical connectors from the second EMC housing 210-2 to the primary load such as the germicidal source 112. The electrical connectors such as electrical harness may be mounted with ferrite materials to curb the unintended conducted emissions from the harness.

Further, in the third EMC housing 210-3, the second compartment 522 may include one or more functional units, such as switched mode power supply (SMPS), which may receive the first input voltage signal (e.g., 120V AC) from the first EMC housing 210-1 via any suitable electrical connectors, such as electrical harness, passing through the second base hole 532-2 in the base bracket 512. Such electrical harness from the first EMC housing 210-1 may carry high-voltage signals with voltages within a range of 120V to 240V at the same or different intervals, to one or more functional units in the second compartment 522 in the third EMC housing 210-3. Such one or more functional units (e.g., SMPS) may generate the second input voltage signal (e.g., 12V DC) and the fourth input voltage signal (e.g., 3V DC, 3.3V DC, or 3.6V DC, etc.) based on the first input voltage signal (e.g., 120V AC). The second input voltage signal may be sent to the second EMC housing 210-2 for driving a fan; however, some examples may also include the second input voltage signal being sent for driving (1) a fan in the first EMC housing 210-1 and (2) the blower 602 in the load unit 106. The fourth input voltage signal (e.g., 3V DC, 3.3V DC, or 3.6V DC, etc.) may power and/or control one or more functional units, such as main controller in the first interior cavity 508 of the first casing 504-1. The fourth input voltage signal (e.g., 3V DC, 3.3V DC, or 3.6V DC, etc.) may also be sent to the load EMC housing 606 via one of the conduits 702, such as conduit 702-2, to power or control on or more functional units therein.

Further, one or more functional units such as lamp controller (in the second interior cavity in the second casing 504-2) may receive the second output voltage signal (e.g., approximately 240V AC) from the first EMC housing 210-1 via any suitable electrical connectors, e.g., the electrical harness, passing through the second base hole 532-2 in the base bracket 512. Such one or more functional units (e.g., lamp controller) may generate the third input voltage signal (e.g., 1000V AC) based on the second output voltage signal (e.g., approximately 240V AC). This third input voltage signal (e.g., 1000V AC) may be sent to one or more functional units in the second EMC housing 210-2 through any suitable electrical connectors internally via the first EMC housing 210-1.

In the load EMC housing 606, the primary load (e.g., the germicidal source 112) may receive high-voltage signals (e.g., 3000V, 15000V, or voltage values therebetween) via the electrical connectors passing internally directly from the second EMC housing 210-2 via the first compartment 520 in the third EMC housing 210-3 and the first conduit 702-1, to drive the germicidal source 112 to emit a germicide at predefined or dynamically defined frequency and energy. Similarly, the blower 602 and the visor assembly may receive the second input voltage signal (e.g., 12V DC) from the third EMC housing 210-3 through suitable electrical connectors passing internally via the second conduit 702-2. Further, one or more functional units may receive the fourth input voltage signal (e.g., 3V DC, 3.3V DC, or 3.6V DC, etc.) from the third EMC housing 210-3 via the second conduit 702-2 to trigger the rotation/movement of the visor 604.

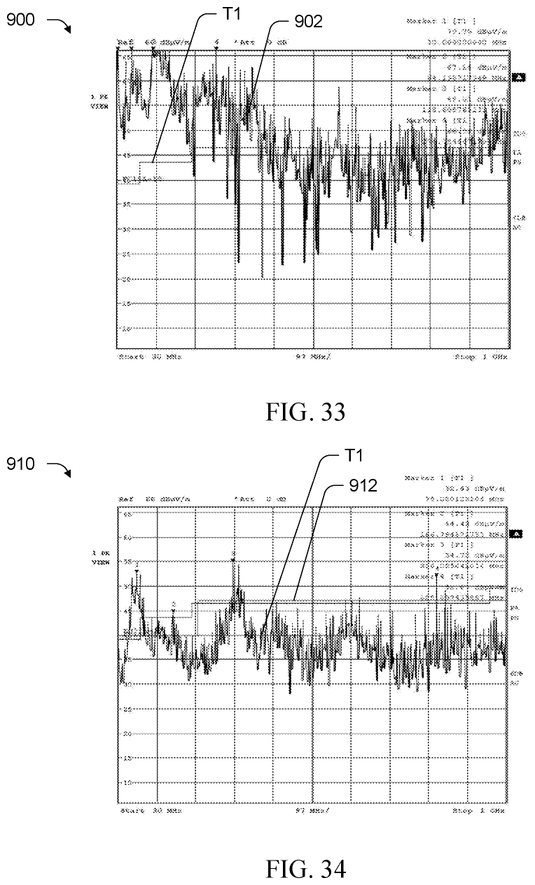

In one embodiment, a robot may be operated with a traditional layout of the underlying functional units (e.g., shown in FIG. 4) for the germicidal source 112 to emit the germicide. The robot with such traditional layout generates unintended electromagnetic emissions beyond the regulatory permissible limits. As illustrated in FIG. 33, the unintended radiated emissions from such robot (with traditional layout of FIG. 4) during operation are shown in the graph 900 with x-axis representing frequency ranging from 30 MHz to 1 GHz, and y-axis representing field strength (in decibel-microvolts per meter) of the unintended radiated emissions on the y-axis. Such robot during operation receives an input voltage signal of 120V AC and fire germicide (e.g., UV light) at a frequency of 55 Hz. In the graph 900, the curve 902 represents the field strength of unintended radiation emissions being significantly above the horizontal threshold line T1 representing the regulatory limits shown in FIG. 5., thereby failing to contain the unintended radiated emissions below the regulatory permissible limits. On the other hand, as illustrated in FIG. 34, the graph 910 shows unintended radiated emissions from the robot 102 implementing the novel EMC system 110 to fire a germicide (e.g., UV light) at a frequency of 55 Hz based on the input voltage signal of 120V AC. In the graph 910, the curve 912 represents that the total unintended radiation emissions having quasi-peak values being reduced below the regulatory limits represented by the horizontal threshold line T1, thereby succeeding in keeping the unintended radiated emissions below the regulatory permissible limits.

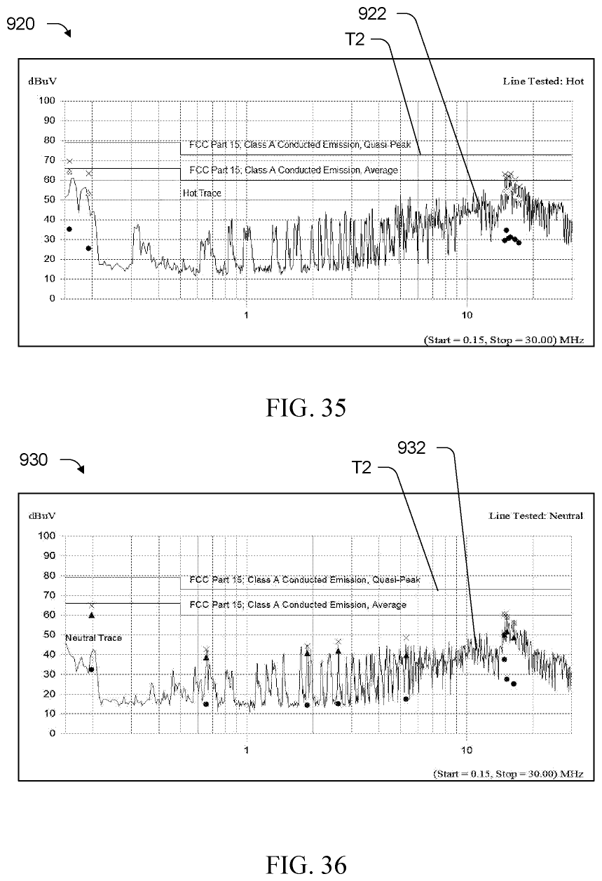

Further, as illustrated in FIG. 35, the unintended conducted emissions (coupled from the EMC system 110 back to the hot or live power line) are represented in the graph 920 with x-axis representing frequency ranging from 150 KHz to 30 MHz, and γ-axis representing field strength (in decibel-microvolts per meter) of the unintended conducted emissions on the y-axis. The robot 102 during operation receives the input voltage signal of 120V AC and fires a germicide (e.g., UV light) at a frequency of 55 Hz. In the graph 920, the curve 922 represents the field strength of unintended conducted emissions on the hot/live power line (e.g., at the supply power harness 808 or the supply cord connected to the AC mains) being significantly below the horizontal threshold line T2 representing the regulatory limits shown in FIG. 5., thereby demonstrating success in reducing the unintended conducted emissions on the hot power line below the regulatory permissible limits.

Similarly, as illustrated in FIG. 36, the unintended conducted emissions (coupled from the EMC system 110 back to the neutral line) are represented in the graph 932 with x-axis representing frequency ranging from 150 KHz to 30 MHz, and γ-axis representing field strength (in decibel-microvolts per meter) of the unintended conducted emissions on the y-axis. The robot 102 during operation receives the input voltage signal of 120V AC and fires a germicide (e.g., UV light) at a frequency of 55 Hz. In the graph 930, the curve 932 represents the field strength of unintended conducted emissions on the neutral power line (e.g., at the supply power harness 808 or the supply cord connected to the AC mains) being significantly below the horizontal threshold line T2 representing the regulatory limits shown in FIG. 5., thereby demonstrating success in reducing the unintended conducted emissions on the neutral line below the regulatory permissible limits.

Various kinds, sizes, shapes, and materials of various components including those not necessarily depicted in the attached drawings may also be envisaged by invention(s) covered in the present application. Notably, the figures and examples are not meant to limit the scope of the present application to a single embodiment, but other embodiments are possible by way of interchange of some or all of the described or illustrated elements.

While the foregoing written description of the subject matter including invention(s) enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above-described embodiments, methods, and examples, but by all embodiments and methods within the concepts described in the present application.

1. An apparatus for improving electromagnetic compatibility of an equipment, the apparatus comprising:
a first housing defining a first interior volume and a first plurality of openings to the first interior volume, the first plurality of openings including a first side opening and a first lateral opening, wherein the first housing includes a first outer plate mounted to a first panel carrying a first group of components and a first inner plate including the first lateral opening;
a second housing defining a second interior volume and a second plurality of openings to the second interior volume, the second plurality of openings including a second side opening and a second lateral opening, the second housing including a second outer plate mounted to a second panel carrying a second group of components and a second inner plate including the second lateral opening, wherein the second inner plate is mounted in contact with the first inner plate with the second lateral opening axially aligned with the first lateral opening; and
a third housing defining a third interior volume and a third plurality of openings to the third interior volume, the third plurality of openings including a first set of openings and a second set of openings, wherein the third housing is mounted on both the first housing and the second housing with the first set of openings axially aligned with the first side opening and the second set of openings axially aligned with the second side opening.

2. The apparatus of claim 1, wherein each of the first housing, the second housing, and the third housing are made up of electrically conductive materials.

3. The apparatus of claim 1, wherein the first group of components and the second group of components are operationally connected via an electrical connector passing internally between the first housing and second housing, the electrical connector passing through the first lateral opening and the second lateral opening, wherein the electrical connector is mounted with a ferrite material.

4. The apparatus of claim 1, wherein the third housing further includes a first compartment and a second compartment, the first compartment includes at least one electrical switching component and electrically communicates with the first housing via a first electrical connector passing through the first side opening, the second compartment communicating with the second housing via a second electrical connector passing through the second side opening, wherein the second compartment is devoid of electrical switching components.

5. The apparatus of claim 4, wherein the second compartment electrically communicates with another apparatus including a primary load, wherein the second electrical connector extends through the second set of openings to couple with the primary load.

6. The apparatus of claim 4, wherein the second electrical connector is carrying a voltage signal having a voltage within a range of 3000 V to 15000 V.

7. The apparatus of claim 4, wherein the first electrical connector is carrying a voltage signal having a voltage within a range of 120 V to 340 V.

8. The apparatus of claim 4, wherein the third housing further includes a third compartment electrically communicating with another apparatus via a third electrical connector passing through the first set of openings, wherein the another apparatus is coupled to a primary load.

9. The apparatus of claim 1, wherein the first housing is electrically connected to another apparatus configured to filter a power signal to attenuate unwanted noise therefrom, wherein another apparatus provides the filtered power signal to at least one of the components in the first group located in the first housing.

10. The apparatus of claim 9, wherein the first outer plate includes a physical electrical port electrically coupled to the first group of components, the physical port being configured to receive the filtered power signal, wherein the physical electrical port passes through a hole in the first panel to be located within the first interior volume.

11. A system for improving electromagnetic compatibility of an equipment, the system comprising:
a first apparatus including:
a first housing defining a first interior volume and a first plurality of openings to the first interior volume, the first plurality of openings including a first side opening and a first lateral opening, wherein the first housing includes a first outer plate mounted to a first panel carrying a first group of components and a first inner plate including the first lateral opening;
a second housing defining a second interior volume and a second plurality of openings to the second interior volume, the second plurality of openings including a second side opening and a second lateral opening, the second housing including a second outer plate mounted to a second panel carrying a second group of components and a second inner plate including the second lateral opening, wherein the second inner plate is mounted in contact with the first inner plate with the second lateral opening axially aligned with the first lateral opening; and
a third housing defining a third interior volume and a third plurality of openings to the third interior volume, the third plurality of openings including a first set of openings and a second set of openings, wherein the third housing is mounted on both the first housing and the second housing with the first set of openings axially aligned with the first side opening and the second set of openings axially aligned with the second side opening; and
a second apparatus operably connected to the first apparatus, the second apparatus including a fourth housing defining a fourth interior volume and at least one opening to the fourth interior volume, wherein the fourth housing including a functional unit mounted thereto that is electrically connected to at least one of the first group of components and the second group of components.

12. The system of claim 11, wherein each of the first housing, the second housing, and the third housing are made up of electrically conductive materials.

13. The system of claim 11, wherein the first group of components and the second group of components are operationally connected via an electrical connector passing internally between the first housing and second housing, the electrical connector passing through the first lateral opening and the second lateral opening, wherein the electrical connector is mounted with a ferrite material.

14. The system of claim 11, wherein the third housing further includes a first compartment and a second compartment, the first compartment includes at least one electrical switching component and electrically communicates with the first housing via a first electrical connector passing through the first side opening, the second compartment communicating with the second housing via a second electrical connector passing through the second side opening, wherein the second compartment is devoid of electrical switching components.

15. The system of claim 14, wherein the second compartment electrically communicates with another apparatus including a primary load, wherein the second electrical connector extends through the second set of openings to couple with the primary load.

16. The system of claim 14, wherein the second electrical connector is carrying a voltage signal having a voltage within a range of 3000 V to 15000 V.

17. The system of claim 14, wherein the first electrical connector is carrying a voltage signal having a voltage within a range of 120 V to 340 V.

18. The system of claim 14, wherein the third housing further includes a third compartment electrically communicating with another apparatus via a third electrical connector passing through the first set of openings, wherein the another apparatus is coupled to a primary load.

19. The system of claim 11, wherein the functional unit is configured to filter a power signal to attenuate unwanted noise therefrom, wherein the functional unit provides the filtered power signal to at least one of the components in the first group.

20. The system of claim 19, wherein the first outer plate includes a physical electrical port electrically coupled to the first group of components, the physical electrical port being configured to receive the filtered power signal, wherein the physical electrical port passes through a hole in the first panel to be located within the first interior volume.
